(19) United States
(12) Patent Application Publication
(10) Pub. No.: US 2004/0050326 A1
(43) Pub. Date: Mar. 18, 2004

(54) Apparatus and method for automatically controlling gas flow in a substrate processing system

(76) Inventors: Karin Anna Lena Thilderkvist, San Jose, CA (US); Christopher Todd Fulmer, San Jose, CA (US); Paul Comita, Menlo Park, CA (US); Annie A. Karpati, Cupertino, CA (US)

Correspondence Address: Michael A. Bernadicou, APPLIED MATERIALS, INC., Patent Counsel, Legal Affairs Department, P.O. Box 450A, Santa Clara, CA, 95052, US

(21) Appl. No.: 10/243,426

(22) Filed: Sep. 12, 2002

(51) Int. Cl. C23F 1/00; C23C 16/00

(52) U.S. Cl. 118/715; 156/345.33

(57) ABSTRACT

A fluid delivery system for providing fluids to a substrate processing system. The fluid delivery system may include a first manifold having a first inlet, a first outlet, and a second outlet, wherein the first outlet and the second outlet are coupled to the substrate processing system. The fluid delivery system mat further include a first conduit for coupling a first fluid to the first inlet and a flow controller for controlling the flow of the first fluid through the first conduit. The fluid delivery system may also include a computer controlled metering valve coupled to the first outlet.

### FIELD OF THE INVENTION

This invention relates generally to semiconductor fabrication systems, and more specifically to a method and apparatus for delivering one or more gases to a substrate processing system.

### BACKGROUND OF THE INVENTION

Semiconductor devices such as microprocessors and memories are fabricated by various processes, such as depositing a film on a substrate or etching portions of an existing film on a substrate. Of principal concern in many semiconductor manufacturing processes is the difficulty of maintaining process uniformity. For example, a layer deposited on a substrate may exhibit thickness variations across the substrate as well as composition variations within the deposited layer itself. As integrated circuit feature sizes become smaller, it is increasingly important to minimize these variations in order to achieve a deposited layer which exhibits very high thickness and composition uniformities.

Many semiconductor fabrication processes are activated thermally and/or via mass transport. As a result, maintaining optimal process uniformity typically requires adjustments to substrate temperature uniformity and/or gas flow distribution across the surface of the substrate. Prior art semiconductor processing equipment has utilized multi-zone heat sources to adjust the temperature distribution across a substrate in order to compensate for non-uniform mass transport effects. Additionally, prior art semiconductor processing equipment has featured means for distributing process gases according to a desired flow pattern in order to minimize mass transport effects across the surface of a substrate.

Chemical vapor deposition (CVD) processes are commonly used in semiconductor manufacturing to deposit a layer of material onto the surface of a substrate. In an epitaxial silicon or silicon-germanium deposition process, doped or undoped silicon layers are typically deposited onto a substrate using a low-pressure CVD process. In this process, a reactant gas mixture including a source of silicon and, optionally, a dopant gas is heated and passed over a substrate to deposit a silicon film on the substrate surface. The silicon source may be monosilane, dichlorosilane, trichlorosilane, or tetrachlorosilane; the dopant gas may be phosphine, arsine or diborane. Other silicon sources and dopants may also be used. In some instances, a non-reactant carrier gas, such as hydrogen, is also injected into the processing chamber, together with either or both of the reactant or dopant gases.

In a doped or undoped epitaxial silicon deposition process, the crystallographic nature of the deposited silicon is a function of the deposition temperature. Additionally, in some doped epitaxial silicon deposition processes, the temperature dependence of dopant incorporation into the film is inversely proportional to the temperature dependence of the epitaxial silicon deposition rate. As a result, adjusting the temperature distribution across a substrate to optimize the thickness uniformity of a doped epitaxial silicon layer may result in non-uniform dopant incorporation within the expitaxial silicon layer. In other CVD processes, adjusting the temperature distribution across a substrate may result in detrimental changes to electrical and/or physical properties of a deposited film.

U.S. Pat. No. 5,916,369 to Anderson et al. discloses a method and apparatus for controlling the flow rate and composition of a mixture comprising a silicon source gas and a dopant gas across a substrate surface. Referencing FIG. 2, a gas mixture containing a silicon source and a hydrogen carrier gas is injected into chamber 218 from gas sources 202 and 204. Mass flow controllers 203 and 205 independently control the flow rate of the silicon source and the hydrogen carrier gas to chamber 218. The gas mixture flows through two metering valves 211 and 212 which operate as variable restrictors to apportion the flow of silicon bearing gas between different gas inlet ports of chamber 218. A dopant gas is fed from gas source 214, through mass flow controllers 216 and 220, and into the silicon source and hydrogen carrier gas mixture downstream of metering valves 211 and 212. Mass flow controllers 216 and 220 may be used to independently control the dopant gas concentration flowing into different gas inlet ports of chamber 218.

In Anderson et al., metering valves 211 and 212 each may comprise a valve containing a variable orifice which is manually adjusted to control the flow rate of gas passing through the valve body. Typically, a metering valve comprises a needle valve which is manually adjusted to vary flow restriction by the movement of a pointed plug or needle in an orifice or tapered orifice in the valve body. For example, metering valve 211 may be adjusted to have a greater flow restriction than metering valve 212 such that a greater proportion of gases from gas sources 202 and 204 pass through metering valve 212. Alternatively, metering valve 212 may be adjusted to have a greater flow restriction than metering valve 211 such that a greater proportion of gases from gas sources 202 and 204 pass through metering valve 211.

Typically, metering valves such as those described in Anderson et al. are manually adjusted to achieve optimal thickness and composition uniformity for a particular process. However, many applications require that different processes be performed within a single process chamber. Metering valve settings which have been optimized for one process may produce less than optimal results when used for another process, resulting in poor uniformity. Although metering valves may be adjusted to accommodate alternative processes, such adjustments may require excessive system downtime, resulting in undesirable delays.

Accordingly, a need has arisen for a system of supplying process gases to a semiconductor processing system which overcomes these problems. Such a gas distribution system may be useful in several different fabrication processes such as chemical vapor deposition, physical vapor deposition, etching, thermal annealing, thermal oxidation, and other such processes as are commonly used in the manufacture of integrated circuit devices.

### BRIEF DESCRIPTION OF THE DRAWINGS

The present invention is illustrated by way of example, and not by way of limitation, in the figures of the accompanying drawings.

FIG. 1 is a schematic diagram illustrating one embodiment of an apparatus for delivering fluids to a substrate processing system.

FIG. 2 is a schematic diagram illustrating one embodiment of a prior art apparatus for delivering fluids to a substrate processing system.

FIG. 3 is a schematic diagram illustrating one embodiment of a substrate processing system.

FIG. 4 is a schematic diagram illustrating one embodiment of a substrate processing chamber.

FIG. 5 is a schematic diagram illustrating one embodiment of a gas interface adapted to provide gas flow into a process chamber.

FIG. 6 is a schematic diagram illustrating one embodiment of a gas interface adapted to provide gas flow into a process chamber.

FIG. 7 is a schematic diagram illustrating one embodiment of a gas interface adapted to provide gas flow into a process chamber.

FIG. 8 is a schematic diagram illustrating one embodiment of a substrate processing chamber.

FIG. 9 is a schematic diagram illustrating one embodiment of a showerhead adapted to provide gas flow into a process chamber.

FIG. 10 is a schematic diagram illustrating one embodiment of an apparatus for delivering fluids to a substrate processing system.

FIG. 11 is a flow diagram illustrating one embodiment of performing a first process step and a second process step on a substrate.

FIG. 12A is a schematic diagram illustrating one embodiment of a metrology chamber for use with a processing system.

FIG. 12B is a schematic diagram illustrating one embodiment of a metrology chamber for use with a processing system.

FIG. 13 is a flow diagram illustrating one possible method of modifying computer controlled metering valve settings using measurements from a metrology chamber.

FIG. 14A is a graphical depiction of a process recipe.

FIG. 14B is a graphical depiction of another portion of the process recipe depicted in FIG. 14A.

### SUMMARY OF THE INVENTION

A fluid delivery system for providing fluids to a substrate processing system is described herein. In one embodiment, the fluid delivery system may include a first manifold having a first inlet, a first outlet, and a second outlet, wherein the first outlet and the second outlet are coupled to the substrate processing system. The fluid delivery system may further include a first conduit for coupling a first fluid to the first inlet and a flow controller for controlling the flow of the first fluid through the first conduit. The fluid delivery system may also include a computer controlled metering valve coupled to the first outlet.

In another embodiment, the fluid delivery system may include a first manifold having a first inlet, a first outlet, and a second outlet, wherein the first outlet and the second outlet are coupled to the substrate processing system. The fluid delivery system may further include a first conduit for coupling a first fluid to the first inlet and a flow controller for controlling the flow of the first fluid through the first conduit. The fluid delivery system may also include a first metering valve coupled to the first outlet and a second metering valve coupled to the second outlet.

Additional features and advantages of the present invention will be apparent from the accompanying drawings and from the detailed description that follows.

### DETAILED DESCRIPTION OF THE INVENTION

The present invention describes a method and apparatus for delivering process fluids to a substrate processing system. In the following description, numerous specific details are set forth, such as specific materials, machines, and methods, in order to provide a thorough understanding of the present invention. However, one skilled in the art will appreciate that these specific details are not necessary in order to practice the present invention. In other instances, well known equipment features and processes have not been set forth in detail in order to not unnecessarily obscure the present invention.

A processing system having a computer controlled gas delivery system is described herein. The processing system may include a number of chambers for performing various processes involved in semiconductor fabrication. The processing system may include a process chamber for depositing layers of material onto a surface of a substrate held within the process chamber. The layers may be deposited, for example, by a process such as chemical vapor deposition. During a chemical vapor deposition process, a process gas is directed into an interior portion of a process chamber and over a surface of a substrate while the temperature of the substrate is maintained at a particular level, such that a layer is formed on the substrate as the process gas passes over the substrate.

The computer controlled gas delivery system described herein may be used to enhance the control and distribution of gases within a process chamber during substrate processing. For example, the gas delivery system may be used to control the concentration and flow rate of one or more process gases flowing over the surface of a substrate during a chemical vapor deposition process, thereby minimizing thickness and composition variations within a deposited layer.

Computer controlled metering valves and flow controllers may be used to control gas distribution and composition within a plurality of gas inlet manifold channels which direct one or more gases across the surface of a substrate. A system controller may execute a process recipe which contains settings for controlling the computer controlled metering valves and flow controllers. The system controller may automatically control the settings for the computer controlled metering valves and flow controllers based upon variables contained within the process recipe. Consequently, the computer controlled gas delivery system may be used to automatically alter the composition and flow rate of gases passing through the gas channels and across different portions of a substrate during processing.

The computer controlled gas delivery system may be used to automatically adjust computer controlled metering valve and flow controller settings while depositing multiple layers of varying composition and/or thickness over a substrate surface during a single process recipe. For example, a first layer may be deposited over a substrate surface using a first set of computer controlled metering valve and flow controller settings contained within a first process recipe step. Subsequent to depositing the first layer, a second set of computer controlled metering valve and flow controller settings may be accessed from a second process recipe step to deposit a second layer of material over the first layer. Consequently, the computer controlled gas delivery system may used to optimize gas distribution and composition at each process recipe step corresponding to a deposited layer, thereby minimizing thickness and composition variations within each layer.

Alternatively, the computer controlled gas delivery system may be used to deposit one or more layers of varying composition and/or thickness over separate substrates during separate processes. For example, a first set of computer controlled metering valve and flow controller settings may be accessed from a first process recipe to deposit one or more layers over a first substrate during a first process. Subsequently, a second set of computer controlled metering valve and flow controller settings may be accessed from a second process recipe to deposit one or more layers over a second substrate during a second process. As a result, the computer controlled gas delivery system may used to create an optimal gas distribution and composition for each process recipe, corresponding to maximum thickness and composition uniformities for each deposited layer.

The processing system may include a metrology device to measure the thickness and/or composition of a layer deposited on the surface of a substrate. The measurement may be taken at different locations along the surface of the deposited layer. Measurements taken by the metrology device may be used to automatically adjust computer controlled metering valve and flow controller settings in a process recipe to further improve thickness and/or composition uniformities in subsequent deposition processes.

The computer controlled gas delivery system of the present invention may provide significant benefits to a wide variety of processes commonly used in the manufacture of electronic devices. For example, in one embodiment the gas distribution system may be integrated with a chemical vapor deposition (CVD) processing system to control the concentration and flow rate of process gases over the surface of a substrate, thereby minimizing mass transport effects during processing and enhancing thickness and/or composition uniformity of a deposited layer. In alternative embodiments, the gas distribution system may be integrated with other types of processes, such as physical vapor deposition (PVD), etch, thermal anneal, thermal oxidation, and others to improve various process parameters and deposited material properties.

Processing System

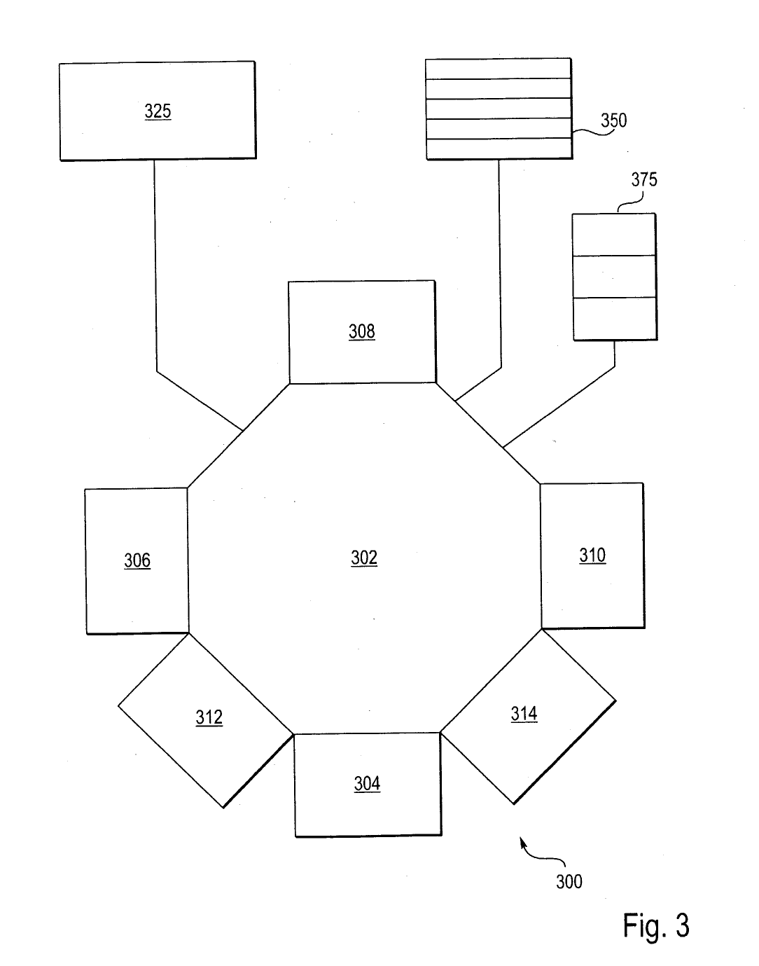

FIG. 3 is a schematic diagram illustrating one embodiment of a substrate processing system 300 having a gas distribution system which is described herein. Processing system 300 may be a cluster processing tool, such as a Centura or Endura processing system manufactured by Applied Materials of Santa Clara, Calif. Processing system 300 may include one or more load-lock chambers 304; one or more process chambers 306, 308, and 310; a metrology chamber 312; and a cooldown chamber 314. Chambers 304, 306, 308, 310, 312, and 314 may be attached to a central transfer chamber 302. A substrate transfer robot may be located within transfer chamber 302 for transferring substrates between chambers 304, 306, 308, 310, 312, and 314.

Processing system 300 may further include a system controller 325 for controlling various operations of processing system 300, power supplies 350 for supplying various forms of energy to processing system 300, and pumps 375 for evacuating various vacuum chambers contained within processing system 300.

System Controller

System controller 325 may control the operation of processing system 300, including the operation of load-lock chambers 304; process chambers 306, 308, and 310; metrology chamber 312; cooldown chamber 314; central transfer chamber 302; power supplies 350; and pumps 375. System controller 325 may also control the operation of computer controlled metering valves and mass flow controllers structured to the computer controlled gas delivery system.

System controller 325 may include a single board computer (SBC) comprising a processor and memory. The SBC processor may include a central processing unit (CPU) such as a Pentium microprocessor manufactured by Intel Corporation of Santa Clara, Calif. In some embodiments, the SBC processor may include an application specific integrated circuit (ASIC) to operate one or more specific components of processing system 300. For example, the SBC processor may include an ASIC to operate computer-controlled metering valves and mass flow controllers. The SBC memory may include various volatile and non-volatile memory devices, such as RAM or EPROMs.

System controller 325 may also include one or more memory storage devices, such as a hard disk drive, a floppy disk drive, or a CD-ROM drive. System controller 325 may further include one or more input/output (I/O) devices, such as a CRT monitor and keyboard; analog input/output boards; digital input/output boards; interface boards; and stepper motor controller boards. The SBC processor, SBC memory, memory storage devices, and input/output devices may communicate via a communications bus.

System Control Software

System controller 325 may control all of the activities of the processing system 300 according to an instruction set defined by system control software. The system control software may be stored in a computer-readable medium and executed by system controller 325. Preferably, system control software is stored on a hard disk drive, but system control software may also be stored on a floppy disk, RAM, a CD-ROM or other types of memory storage devices. The system control software may be written in any conventional programming language, including but not limited to 68000 assembly language, C, C++, Pascal, or Fortran. In a preferred embodiment, the system control software comprises Legacy software developed by Applied Materials of Santa Clara, Calif.

The system control software may be entered into a single file or multiple files using a conventional text editor. If the system control software code is written in a high level language, the system control software code may be compiled, and the resulting compiler code may be linked with an object code of precompiled library routines. To execute the linked compiled object code, a user may invoke the object code, causing system controller 325 to load the code into SBC memory, from which the SBC processor reads and executes the code to perform the tasks identified in the system control software.

The system control software may include one or more sets of computer instructions for managing all operational aspects of processing system 300. For example, the system control software may include computer instructions for managing the movement of wafer transfer mechanisms and the opening and closing of vacuum pump valves. In one embodiment, the system control software may include a chamber manager program for operating and managing priorities of the chamber components associated with process chambers 306, 308, and 310. The chamber manager program may contain a number of subroutines, such as a substrate positioning subroutine that controls substrate lifting mechanisms within a chamber. Thus, substrate position, chamber pressure, substrate temperature, power supply output, and other such parameters which affect processes performed within process chambers 306, 308, and 310 may be controlled by the chamber manager program.

In one embodiment, the system control software may include a gas distribution program for operating a computer controlled gas delivery system. The gas distribution program may include instructions for controlling the settings of computer controlled metering valves, mass flow controllers, and isolation valves. Additionally, the system control software may include a process selector program that allows an operator to enter or select a process recipe and execute that process recipe in a particular process chamber.

It is to be understood that the system control software should not be limited to the specific embodiment of the various programs described herein, and that other sets of programs or other computer instructions that perform equivalent functions are within the scope of the present invention. Additionally, the separate programs described herein could be entirely integrated into a single program, or the tasks of one program could be integrated into the tasks of another program to provide a desired set of tasks.

Process Recipe

Instructions for directing a process chamber to perform a specific process on a substrate may be contained within a process recipe. A process recipe may comprise one or more process steps. Each process step may contain a set of variables that define various process parameters for that recipe step, such as but not limited to gas flow, step duration, microwave or RF bias power levels, magnetic field power levels, cooling gas pressure, chamber wall temperature, chamber pressure, substrate temperature, and susceptor position. Process parameters may be changed between process steps to vary the processing environment within a process chamber. The process recipe variables that define gas flow may include settings for computer controlled metering valves, mass flow controllers, and isolation valves. The valve settings may be stored in a table of valve setting instructions that lists valve settings inputted by a user. Alternatively, the table of valve settings may contain an algorithm for determining valve settings.

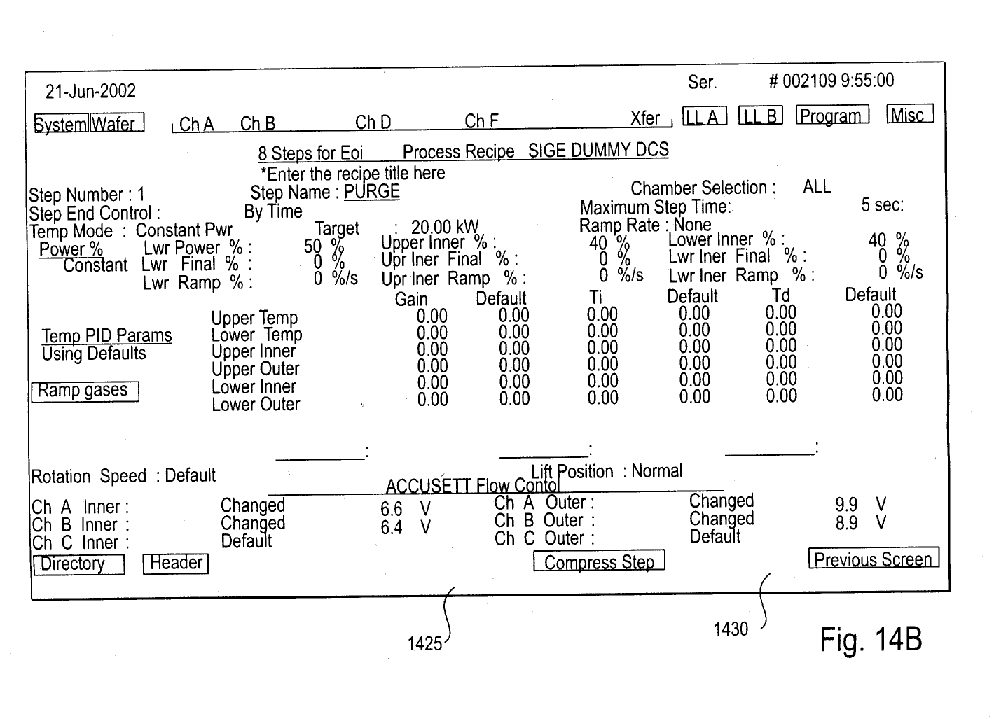

An example process recipe 1405 is depicted graphically in FIG. 14A. Process recipe 1405 contains three process steps: purge process step 1410, ramp process step 1415, and bake process step 1420. Each of process steps 1410, 1415, and 1420 contains variables that define various process parameters for each respective process step. For example, purge process step 1410 has a maximum step time of 5 seconds, ramp process step 1415 has a maximum step time of 90 seconds, and bake process step 1420 has a maximum step time of 45 seconds. Numerous other process parameters are contained within process recipe 1405, such as temperature ramp rate, power supply output, and gas flows. Each these process parameters may be altered between process steps to vary the processing environment within a process chamber.

A process recipe may be stored as a table of process parameter settings on a memory storage device connected to system controller 325, such as a hard drive. To execute a process recipe, the table of process parameter settings may be read into SBC memory and executed by a subroutine within the system control software to perform tasks identified within the process recipe steps. For example, during operation, the chamber manager subroutine program may monitor the various chamber components, determine which components need to be operated based on the process parameters contained within the process recipe, and direct the control of those components responsive to the monitoring and determining steps.

Process Sequence

Instructions for directing processing system 300 to perform a series of operations on a substrate may be contained within a process sequence. The operations may be performed in several different chambers within processing system 300. A process sequence may comprise one or more sequence steps, and each sequence step may contain a process chamber designator and a process recipe designator. For example, a process sequence may include a first sequence step wherein a wafer is transferred from load-lock chamber 304 to designated process chamber 306 where a first process is performed on the wafer as defined by a designated first process recipe. The process sequence may include a second sequence step wherein a wafer is transferred from process chamber 306 to designated process chamber 308 where a second process is performed on the wafer as defined by a designated second process recipe. The process sequence may further include a third process sequence step wherein a wafer is transferred from process chamber 308 to load-lock chamber 304. A process sequence may be stored on a memory storage device connected to system controller 325, such as a hard drive. To execute a process sequence, the sequence may be read into SBC memory and executed by the system control software to perform the series of steps defined within the process sequence.

Prior to processing, a lot of substrates may be placed within load-lock chamber 304 and a process sequence may be assigned to each substrate within the lot of substrates. If each substrate is assigned the same process sequence, the same series of operations may be performed on each substrate. Alternatively, if substrates within the lot are assigned different process sequences, substrates within the lot will be processed differently according to their assigned process sequence.

After a process sequence has been assigned to each substrate within the lot of substrates to be processed, process system 300 may be instructed to process the lot of substrates according to each substrate's assigned sequence. A substrate transfer robot located within transfer chamber 302 may sequentially transfer substrates to a series of chambers as defined in the process sequence. For example, a process sequence may be assigned to each wafer within a lot of twenty-five wafers. Subsequently, the substrate transfer robot may transfer each wafer to one or more process chambers 306, 308, and 310; a cooldown chamber 314; and then back to load-lock chamber 304. Process chambers 306, 308, and 310 may perform various processes on the wafer, such as deposition, etching, or annealing. Cooldown chamber 314 may be used to cool each wafer before returning the wafer to load-lock chamber 304. After the lot of twenty-five wafers has been processed, load-lock chamber 304 may be vented to atmospheric pressure, opened, and the wafers may be removed for subsequent processing in other wafer processing systems.

System Software Operation

During operation, the process selector program is used to identify a process recipe and a process chamber in which the process recipe is to be performed. The process selector program code executes a designated process recipe by passing the process recipe parameters to the chamber manager program code, which controls multiple processing tasks in different process chambers according to the process recipe determined by the process selector program. The chamber manager program controls the execution of process recipes within the process chambers through instruction sets which control operation of the process chamber components. The chamber manager instruction sets may include, for example, a substrate positioning instruction set that controls robot components that load and remove a substrate onto a susceptor. The chamber manager instruction set may also include a pressure control instruction set that controls the evacuation of gas from a process chamber. A metrology program code may include instructions for taking surface uniformity measurements of a substrate by means of a metrology device, such as metrology chamber 312.

During processing, the chamber manager program selectively calls the chamber component instruction sets in accordance with the particular process recipe being executed, schedules the chamber component instruction sets, monitors operation of the various chamber components, determines which components need to be operated based on the process parameters for the process recipe to be executed, and causes execution of a chamber component instruction set responsive to the monitoring and determining steps.

The gas distribution program code may include a valve setting instruction set for controlling settings of computer controlled metering valves, mass flow controllers, and isolation valves. Consequently, the gas distribution program code may be used to actuate the computer controlled metering valves, mass flow controllers, and isolation valves structured to the computer controlled gas delivery system.

A valve setting instruction set may be used to adjust valve settings for computer controlled metering valves from a table of valve settings entered into the process selector program code. The valve settings may include separate valve settings for different process recipes performed within a particular process chamber. The valve settings may also include separate valve settings for different layers that may be deposited on a substrate during a single process recipe. As a result, the valve setting instruction set may provide separate valve settings for each layer deposited onto a surface of a substrate. Consequently, uniformity may be optimized for each deposited layer.

The valve setting instruction set may adjust computer controlled metering valve settings based upon uniformity measurement taken during processing. For example, a metrology program may determine thickness uniformity of a deposited layer based upon output signals provided by metrology chamber 312 using, for example, Legacy software. The valve setting instruction set algorithm may subsequently calculate new computer controlled metering valve settings based upon the measured thickness uniformity. The new computer controlled metering valve settings may be incorporated into the table of valve settings using, for example, a SECS trace program. Using the new computer controlled metering valve settings, a process chamber may subsequently produce substrates having enhanced uniformity.

Process Chamber

Referencing FIG. 3, process chambers 306, 308, and 310 may include a process chamber used to deposit layers over a substrate. The layers may be deposited by numerous processes such as chemical vapor deposition (CVD), physical vapor deposition (PVD), or other such processes as are commonly used in the fabrication of electronic devices. The gas distribution system of the present invention may be incorporated into a variety of substrate processing systems in order to enhance the control of two or more process gas flows within a process chamber. Alternatively, the gas distribution system may be used to enhance the control of one or more process gases flows and one or more inert gas flows within a process chamber. In the present invention, a process gas is defined as a gas or gas mixture which acts to deposit, remove, or treat a film on a substrate placed in a processing chamber. An inert gas is defined as a gas which is substantially non-reactive with chamber features and substrates placed in a deposition chamber at particular process temperatures.

For example, the gas distribution system of the present invention may be integrated with a chemical vapor deposition (CVD) processing system to control the flow of process gases over the surface of a substrate, thereby enhancing thickness and/or composition uniformity of a deposited layer. Alternatively, the gas distribution system may be integrated with a physical vapor deposition (PVD) processing system, an etch processing system, or any of a variety of other substrate processing systems as are commonly used in the manufacture of electronic devices.

For illustrative purposes, the gas distribution system of the present invention will be described herein in reference to a CVD processing system. In a typical CVD process, a process gas is passed through a process chamber and over a substrate. The substrate is maintained at a particular temperature such that a layer is formed on the substrate as the process gas passes over the substrate. Several varieties of CVD chambers are manufactured by Applied Materials of Santa Clara, Calif., including the Epi Centura, Epi xP Centura, and Epi Centura 300.

CVD Process Chamber with Side Gas Injection

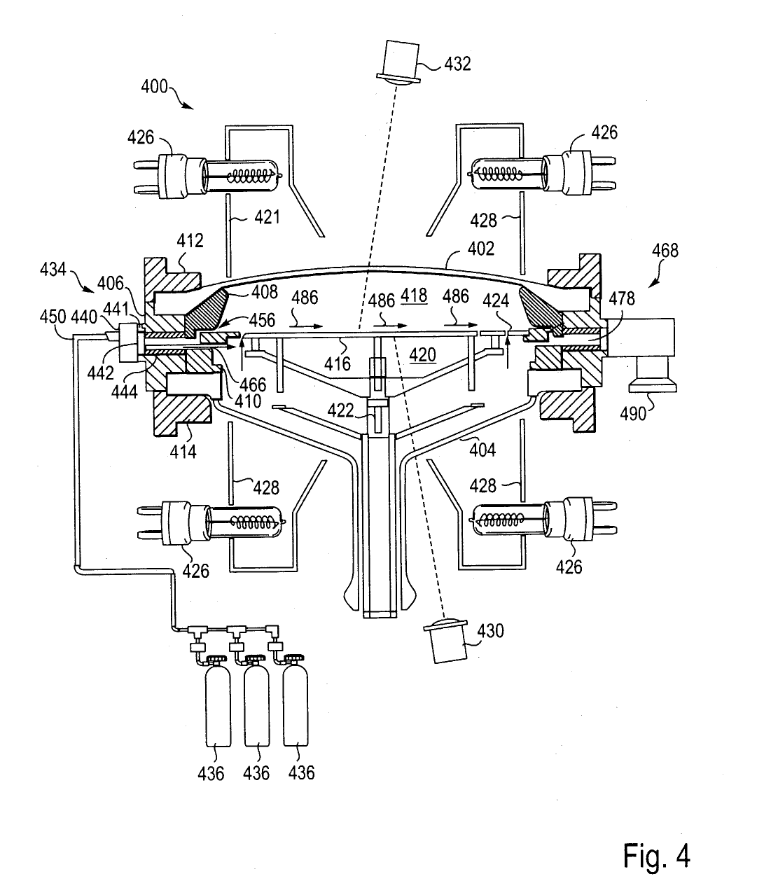

FIG. 4 is a schematic diagram illustrating one embodiment of a CVD process chamber 400. Process chamber 400 may be substantially similar to process chambers 306, 308, and/or 310 described above in reference to FIG. 3. Process chamber 400 may include an upper dome 402, a lower dome 404, and a sidewall 406 positioned between upper dome 402 and lower dome 404. Cooling fluid may be circulated through sidewall 406 to cool o-rings which seal upper dome 402 and lower dome 404 to sidewall 406. An upper liner 408 and a lower liner 410 may be mounted against an inside surface of sidewall 406. Upper dome 402 and lower dome 404 may be formed from a transparent material to allow heating light to pass through into process chamber 400. An upper clamping ring 412 may extend around the periphery of an outer surface of upper dome 402. A lower clamping ring 414 may extend around the periphery of an outer surface of lower dome 404. Upper clamping ring 412 and lower clamping ring 414 may be secured together so as to clamp upper dome 402 and lower dome 404 to sidewall 406.

A susceptor 416 may be located within process chamber 400. Susceptor 416 may be adapted to removeably support a wafer in an approximately horizontal position. Susceptor 416 may extend transversely across process chamber 400 to divide process chamber 400 into an upper portion 418 above susceptor 416, and a lower portion 420 below susceptor 416. Susceptor 416 may be mounted on a shaft 422 that extends vertically downward from the center of the bottom surface of susceptor 416. Shaft 422 may be connected to a motor that rotates shaft 422 and thereby rotates susceptor 416 and a wafer supported by susceptor 416. An annular preheat ring 424 may be connected at its outer periphery to the inner periphery of lower liner 410 and may extend around susceptor 416. Annular preheat ring 424 may be in the same plane as susceptor 416, with the inner periphery of annular preheat ring 424 separated by a gap from the outer periphery of susceptor 416.

In one embodiment, a plurality of lamps 426 may be mounted around process chamber 400. Reflectors 428 may be located around lamps 426 to prevent energy radiated by lamps 426 from radiating away from process chamber 400. Reflectors 428 may also be formed to reflect radiant energy towards upper dome 402 and lower dome 404. Lamps 426 may radiate energy through the upper dome 402 and lower dome 404 to heat susceptor 416 and annular preheat ring 424. Upper dome 402 and lower dome 404 may be made of a transparent material, such as quartz, so that energy radiated by lamps 426 may pass through upper dome 402 and lower dome 404. In other embodiments, heating devices other than lamps, such as resistance heaters or RF inductive heaters, may be used to heat susceptor 416 and annular preheat ring 424.

Susceptor 416 and annular preheat ring 424 may be formed from a material that is opaque to radiation emitted by lamps 426, such as silicon carbide coated graphite. Thus, susceptor 416 and annular preheat ring 424 may be more readily heated by energy radiated from lamps 426. A lower infrared temperature sensor 430, such as a pyrometer, may be mounted below lower dome 404, and may face the bottom surface of susceptor 416 through lower dome 404. Lower infrared temperature sensor 430 may be used to monitor the temperature of susceptor 416 by receiving infrared radiation emitted from susceptor 416 when susceptor 416 is heated. An upper infrared temperature sensor 432 may be mounted above upper dome 402 facing the top surface of susceptor 416 through upper dome 402. Upper infrared temperature sensor 432 may be used to monitor the temperature of a wafer supported by susceptor 416.

Process chamber 400 may be a “cold wall” reactor wherein sidewall 406, upper liner 408, and lower liner 410 are at a substantially lower temperature than preheat ring 424 and susceptor 416 during processing. For example, in a process to deposit an epitaxial silicon film on a wafer, susceptor 416 and a wafer supported by susceptor 416 may be heated to a temperature of between 900-1200° C. The sidewall and liners may be maintained at a lower temperature of approximately 400-600° C. by cooling fluid circulated through sidewall 406.

Process chamber 400 may include a gas interface 434 positioned in a side of process chamber 400. Gas interface 434 may be adapted to transmit gases from one or more gas sources 436 into process chamber 400. Gas sources 436 may include process gases and inert gases. Gas interface 434 may include a connector cap 440, a baffle 442, and an insert plate 444 positioned within sidewall 406. Upper and lower fluid conduits 441 and 466 may be formed in connector cap 440 and insert plate 444. Process chamber 400 may further include a passage 456 formed between upper liner 408 and lower liner 410. Passage 456 may be fluidly connected to upper portion 418 of process chamber 400. Process gas from gas sources 436 may pass through connector cap 440, baffle 442, insert plate 444, and passage 456 into upper portion 418 of process chamber 400.

During operation, one or more gases are supplied to gas interface 434 by means of inlet ports 450. Gases from inlet ports 450 flow through connector cap 440 and bank against the upstream surface of baffle 442. The gases are directed through holes formed in baffle 442 into upper and lower conduits 441 and 466 formed in insert plate 444. Inlet ports 450, connector cap 440, baffle 442, and upper and lower conduits 441 and 466 may form independent flow pathways for each gas entering process chamber 400. As a result, each gas flowing into each inlet port and through connector cap 440, baffle 442, and insert plate 444 along upper and lower conduits 441 and 466 may be kept separate from other gases entering process chamber 400. From upper conduits 441, gases may flow across preheat ring 424, susceptor 416 and a wafer supported by susceptor 416 in the direction indicated by arrows 486. The gas flow profile from upper conduits 441, across preheat ring 424 and a wafer may be predominantly laminar.

In one embodiment, process gases from lower conduits 466 and upper conduits 441 may both be directed into upper portion 418 of process chamber 400. In an alternative embodiment, an inert gas may be directed through lower conduits 466 into lower portion 420 of process chamber 400. For example, an inert purge gas such as hydrogen or nitrogen may be directed into lower portion 420 of process chamber 400 in order to prevent deposition on the back side of susceptor 416. An inert purge gas may be fed into lower portion 420 at a rate which develops a positive pressure within lower portion 420 with respect to the process gas pressure in upper portion 418, thereby preventing process gas from entering lower portion 420.

Gases entering process chamber 400 from upper and lower conduits 441 and 466 may be evacuated from process chamber 400 through outlet 468. Outlet 468 may be positioned in the side of process chamber 400 opposite gas interface 434. Outlet 468 may include an exhaust passage 478 which extends from the upper chamber portion 418 to the outside diameter of sidewall 406. Exhaust passage 478 may be coupled to outlet connector 490 on the exterior of sidewall 406. Outlet connector 490 may be coupled to a vacuum source, such as a pump, by means of an exhaust foreline. The vacuum source may be used to create low or reduced pressure in chamber 400 during processing. Thus, process gas fed into process chamber 400 may be evacuated through exhaust passage 478 and outlet connector 490 into an exhaust foreline.

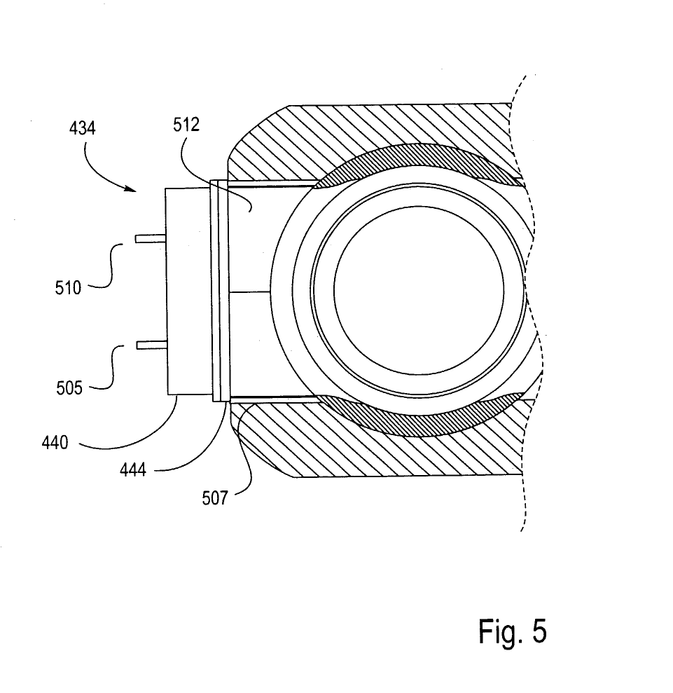

FIG. 5 illustrates one embodiment of gas interface 434 adapted to provide two gas flow channels into upper portion 418 of process chamber 400. In this embodiment, gas interface 434 may include a first port 505 and a second port 510 connected to a first channel 507 and a second channel 512, respectively. During substrate processing, a first gas flow entering first port 505 may flow through first channel 507 and across a first portion of a substrate positioned on susceptor 416. Similarly, a second gas flow entering second inlet port 510 may flow through second channel 512 and across a second portion of the substrate.

In one embodiment, the flow of gas through first channel 507 may be controlled independently from the flow of gas through second channel 512. Consequently, the flow of gas across first and second portions of a substrate positioned on susceptor 416 may be varied to more accurately control the uniformity of a layer deposited on the substrate. For example, a higher flow of gas may be directed through first channel 507 than through second channel 512 in order to increase the thickness uniformity of a particular deposited layer.

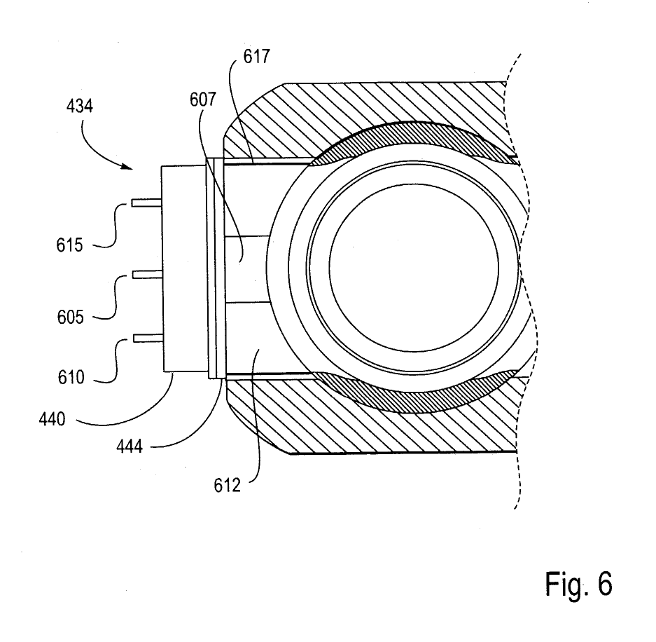

FIG. 6 illustrates another embodiment of gas interface 434 adapted to provide three gas flow channels into upper portion 418 of process chamber 400. In this embodiment, gas interface 434 may include a central inlet port 605, a first outside inlet port 610, and a second outside inlet port 615 connect to a central channel 607, a first outside channel 612, and a second outside channel 617, respectively. During substrate processing, a first gas flow entering central inlet port 605 may flow through central channel 607 and across a central portion of a substrate positioned on susceptor 416. A second gas flow entering first outside inlet port 610 may flow through first outside channel 612 and across a first outside portion of the substrate. A third gas flow entering second outside inlet port 615 may flow through second outside channel 617 and across a second outside portion of the substrate.

In one embodiment, the flow of gas through central channel 607 may be controlled independently from the flow of gas through first outside channel 612 and second outside channel 617. Consequently, the flow of gas across the central portion of a substrate positioned on susceptor 416 may be varied with respect to the flow of gas across the first and second outside portions of the substrate to more accurately control the uniformity of a layer deposited on the substrate. For example, a higher flow of gas may be directed through central channel 607 than through first outside channel 612 and second outside channel 617 in order to increase the thickness uniformity of a particular deposited layer.

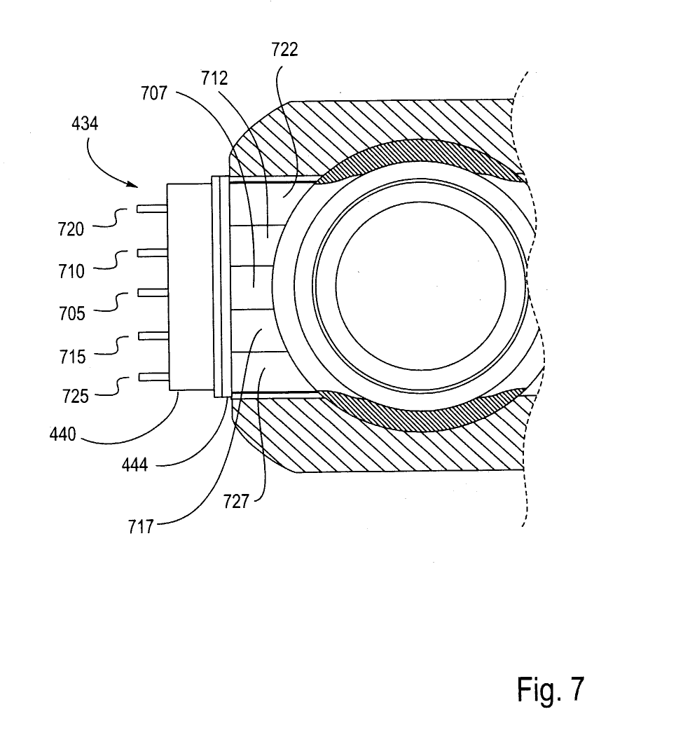

FIG. 7 illustrates yet another embodiment of gas interface 434 adapted to provide five gas flow channels into upper portion 418 of process chamber 400. In this embodiment, gas interface 434 may include a central inlet port 705, a first middle inlet port 710, a second middle inlet port 715, a first outside inlet port 720, and a second outside inlet port 725 connected to a central channel 707, a first middle channel 712, a second middle channel 717, a first outside channel 722, and a second outside channel 727, respectively. During substrate processing, a first gas flow entering central inlet port 705 may flow through central channel 707 and across a central portion of a substrate positioned on susceptor 416. A second gas flow entering first middle inlet port 710 may flow through first middle channel 712 and across a first middle portion of the substrate. A third gas flow entering second middle inlet port 715 may flow through second middle channel 717 and across a second middle portion of the substrate. A fourth gas flow entering first outside inlet port 720 may flow through first outside channel 722 and across a first outside portion of the substrate. A fifth gas flow entering second outside inlet port 725 may flow through second outside channel 727 and across a second outside portion of the substrate.

In one embodiment, the flow of gas through central channel 707, first outside channel 722, and second outside channel 727 may be controlled independently from the flow of gas through first middle channel 712 and second middle channel 717. Consequently, the flow of gas across the central, first outside, and second outside portions of a substrate positioned on susceptor 416 may be varied with respect to the flow of gas across the first and second middle portions of the substrate to more accurately control the uniformity of a layer deposited on the substrate. For example, a higher flow of gas may be directed through central channel 707, first outside channel 722, and second outside channel 727 than through first middle channel 712 and second middle channel 717 in order to increase the thickness uniformity of a particular deposited layer.

The embodiments illustrated in FIGS. 5, 6, and 7 should not be interpreted as limiting as one of ordinary skill in the art will recognize that gas interface 434 may be structured to provide any number of gas flow channels into upper portion 420 of process chamber 400. Additionally, the described gas flows are merely exemplary and other gas flows may be apportioned between different gas flow channels as required for particular processes.

CVD Process Chamber with Showerhead Gas Injection

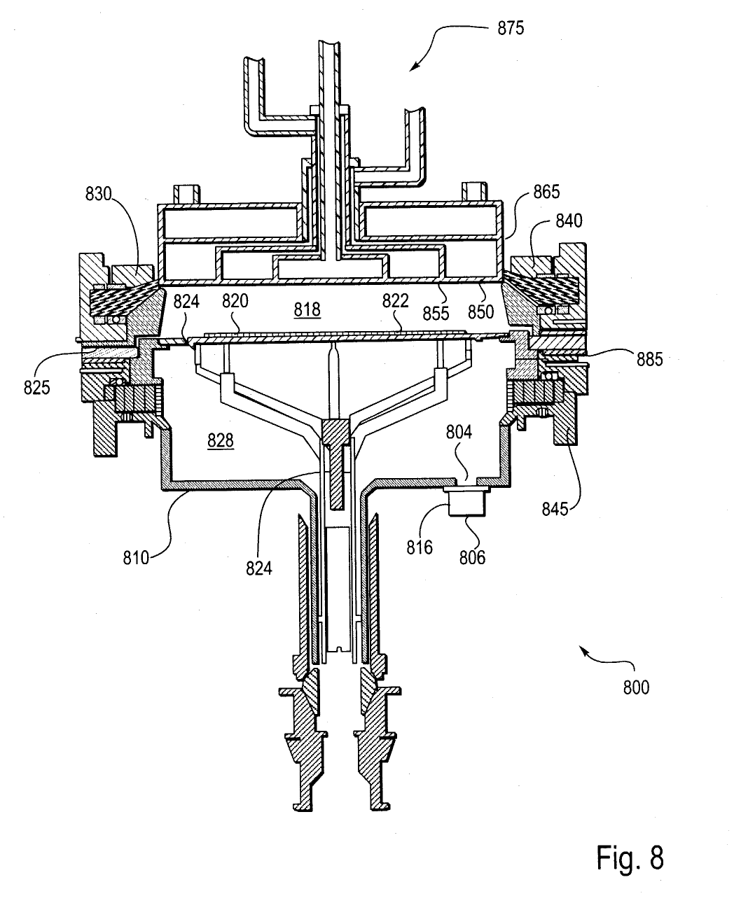

FIG. 8 illustrates process chamber 800, an alternative embodiment of a CVD process chamber. Process chamber 800 may be substantially similar to process chambers 306, 308, and/or 310 described above in reference to FIG. 3. Process chamber 800 may include showerhead 815, lower chamber wall 810, and a sidewall 825 between showerhead 815 and lower chamber wall 810. Cooling fluid may be circulated through sidewall 825 to cool o-rings which seal showerhead 815 and lower chamber wall 810 to sidewall 825. An upper liner 830 and a lower liner 835 may be mounted against an inside surface of sidewall 825. An upper clamping ring 840 may extend around the periphery of an outer surface of showerhead 815. A lower clamping ring 845 may extend around the periphery of an outer surface of lower chamber wall 820. Upper clamping ring 840 and lower clamping ring 845 may be secured together so as to clamp showerhead 815 and lower chamber wall 810 to sidewall 825.

A susceptor 822 may be located within process chamber 800. Susceptor 822 may be adapted to removeably support wafer 820 in an approximately horizontal position. Susceptor 822 may extend transversely across process chamber 800 to divide process chamber 800 into an upper portion 818 above susceptor 822, and a lower portion 828 below susceptor 822. Susceptor 822 may be mounted on a shaft 824 that extends vertically downward from the center of the bottom surface of susceptor 822. An annular preheat ring 824 may be connected at its outer periphery to the inner periphery of lower liner 835 and may extend around susceptor 822. Annular preheat ring 824 may be in the same plane as susceptor 822, with the inner periphery of annular preheat ring 824 separated by a gap from the outer periphery of susceptor 822. In one embodiment, susceptor 822 and annular preheat ring 824 may be heated by means of a resistance heater contained within susceptor 822. In other embodiments, RF inductive heaters, lamps, or other such heating devices may be used to heat susceptor 822 and annular preheat ring 824. The temperature of susceptor 822 may be monitored by means of a thermocouple embedded within susceptor 822.

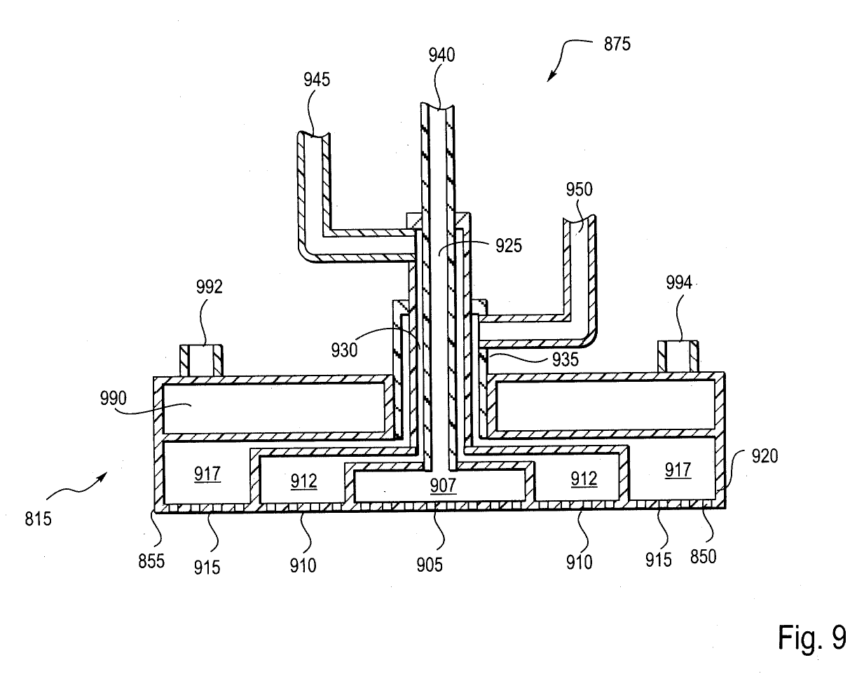

One or more process gases may be injected into upper portion 818 of process chamber 800 through a plurality of orifices 850 extending through a lower surface 855 of showerhead 815. Orifices 850 may be arranged in a plurality of regions or zones on lower surface 855 of showerhead 815. As shown in FIG. 9, orifices 850 may be arranged in a center region 905, a middle region 910, and an outer region 915. Middle region 910 may be arranged in an annular configuration encircling center region 905 and outer region 915 may be arranged in an annular configuration encircling middle region 910 and extending adjacent to an outer periphery 920 of showerhead 815.

Showerhead 815 may further include center passageway 907, middle passageway 912 and outer passageway 917. Orifices contained within center region 905 of showerhead 815 may connect with center passageway 907. Similarly, orifices contained within middle region 910 may connect with middle passageway 912. In like fashion, orifices contained within outer region 915 may connect with outer passageway 917.

Process chamber 800 may further include a gas interface 875 positioned in a top portion of process chamber 800 and connected to showerhead 815. Gas interface 875 may be adapted to direct gas from one or more gas sources through showerhead 815 and into upper portion 818 of process chamber 800. Referencing FIG. 9, gas interface 875 may include center conduit 925, middle conduit 930, and outer conduit 935. Center passageway 907 may be connected to center conduit 925; middle passageway 912 may be connected to middle conduit 930; and outer passageway 917 may be connected to outer conduit 935. Center conduit 925 may be arranged coaxially along a portion of middle conduit 930 and outer conduit 935. Similarly, middle conduit 930 may be arranged coaxially along a portion of outer conduit 935.

Gas interface 875 may further include center inlet port 940, middle inlet port 945, and outer inlet port 950. Center inlet port 940, middle inlet port 945, and outer inlet port 950 may be structured and arranged to provide process gas from one or more gas sources to gas interface 875. Center inlet port may be connected to center conduit 925; middle inlet port 945 may be connected to middle conduit 930; and outer inlet port 950 may be connected to outer conduit 935. Center inlet port 940, middle inlet port 945, and outer inlet port 950 may be connected to one or more gas supply lines, which are in turn connected to gas sources, such as gas cylinders.

As in the previous embodiment, process chamber 800 may be a “cold wall” reactor wherein sidewall 825, upper liner 830, and lower liner 835 are at a substantially lower temperature than preheat ring 824 and susceptor 822 during processing. Additionally, one or more channels 990 having an inlet 992 and an outlet 994 may be formed in showerhead 815. A fluid may be directed into inlet 992, through channels 990, and out of outlet 994 to heat or cool showerhead 815 during operation of process chamber 800.

In operation, one or more gases may be supplied to gas interface 875 through center inlet port 940, middle inlet port 945, and outer inlet port 950. Gas from center inlet port 940 may flow through center conduit 925, center passageway 907, and orifices in center region 905 into upper portion 818 of process chamber 800. Gas from middle inlet port 945 may flow through middle conduit 930, middle passageway 912, and orifices in middle region 910 into upper portion 818 of process chamber 800. Gas from outer inlet port 950 may flow through outer conduit 935, outer passageway 917, and orifices in outer region 915 into upper portion 818 of process chamber 800. Inlet ports 940, 945, and 950; conduits 925, 930, and 935; and passageways 907, 912, and 917 may form independent flow pathways for each gas entering process chamber 800. As a result, each gas flowing into each inlet port and through each conduit and passageway may be kept separate until the gases enter upper portion 818 of process chamber 800.

Gases entering process chamber 800 from showerhead 815 may be evacuated from process chamber 800 through outlet 816. Outlet 816 may be formed in lower chamber wall 810 of process chamber 800. Outlet 816 may include an exhaust passage 804 which extends from lower chamber portion 828 to the lower surface of lower chamber wall 810. Exhaust passage 804 may be coupled to outlet connector 806 on the exterior of lower chamber wall 810. Outlet connector 806 may be coupled to a vacuum source, such as a pump, by means of an exhaust foreline. The vacuum source may be used to create low or reduced pressure in chamber 800 during processing. Thus, process gas fed into process chamber 800 may be evacuated through exhaust passage 804 and outlet connector 806 into an exhaust foreline.

Gas entering center inlet port 940 may initially contact a central portion of a substrate positioned on susceptor 822; gas entering middle inlet port 945 may initially contact a middle annular portion of the substrate; and gas entering outer inlet port 950 may initially contact an outer annular portion of the substrate. After entering upper portion 818 of process chamber 800, process gases may flow radially across wafer 820, susceptor 822, and preheat ring 824.

In one embodiment, the flow of gas through center inlet port 940 and outer inlet port 945 may be controlled independently from the flow of gas through middle inlet port 945. Consequently, the flow of gas across the central and outer annular portions of a substrate positioned on susceptor 822 may be varied with respect to the flow of gas across the middle annular portion of the substrate to more accurately control the uniformity of a layer deposited on the substrate. For example, a higher flow of gas may be directed through the orifices in center region 905 and outer region 915 than through the orifices in middle region 910 in order to increase the thickness uniformity of a particular deposited layer.

FIG. 8 should not be interpreted as limiting as one of ordinary skill in the art will recognize that gas interface 875 may be structured to provide any number of gas flow channels into upper portion 818 of process chamber 800. Additionally, the described gas flows are merely exemplary and other gas flows may be apportioned between different inlet ports and showerhead regions as required for particular processes.

Gas Delivery System

As previously discussed, a process chamber may include a gas interface adapted to provide multiple gas flow channels or regions to an interior portion of a process chamber and across portions of a substrate positioned in the process chamber. For example, FIG. 5 illustrates one embodiment of gas interface 434 adapted to provide two gas flow channels, FIG. 6 illustrates another embodiment of gas interface 434 adapted to provide three gas flow channels, and FIG. 7 illustrates yet another embodiment of gas interface 434 adapted to provide five gas flow channels. Similarly, FIG. 9 illustrates an embodiment of a gas interface 875 adapted to provide three gas flow regions within process chamber 800.

In each of these examples, a gas delivery system may be arranged to direct one or more gases into each gas flow channel. One or more metering valves may be structured to the gas delivery system such that the total gas flow introduced into the gas delivery system may be apportioned between the gas flow channels. Consequently, the flow of gas over portions of a substrate positioned in a process chamber may be controlled with greater accuracy, thereby minimizing thickness and composition variations within layers deposited onto the surface of a substrate. For example, with respect to FIG. 6, one or more metering valves may be used to apportion a greater or lesser flow rate of gas through first outside channel 612 and second outside channel 617 than central channel 607 to increase the thickness uniformity of a particular layer deposited onto a substrate.

In the following descriptions, the term “manifold” is generally used to describe a plurality of conduits arranged to combine two or more fluid flow inlets into a single fluid flow outlet, or a plurality of conduits arranged to divide a single fluid flow inlet into two or more fluid flow outlets. Fluid flow conduits used to construct a manifold may be formed from a variety of materials as are commonly employed in semiconductor manufacturing systems, such as stainless steel high purity gaslines.

Gas Delivery System 1

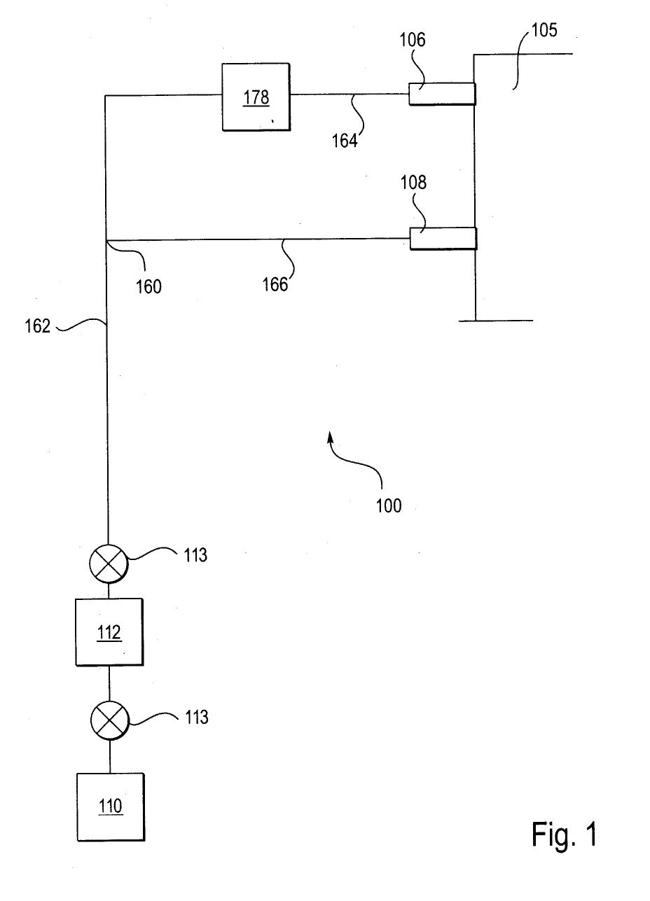

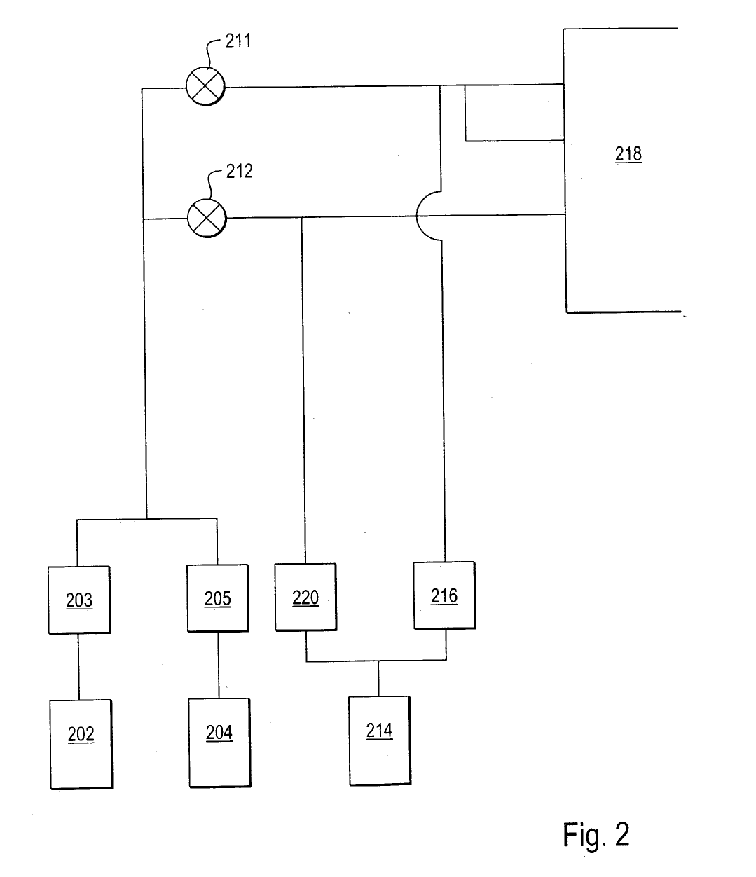

FIG. 1 shows a schematic diagram illustrating one embodiment of a gas delivery system 100 for controlling the flow of gas to gas interface 105. Gas interface 105 may include a first inlet port 106 and a second inlet port 108. In one embodiment, gas interface 105 may be substantially similar to gas interface 434 in FIG. 5, which is structured to provide two gas flow channels into upper portion 418 of process chamber 400. Consequently, during substrate processing, a first gas flow entering first inlet port 106 may be directed to flow across a first portion of a substrate contained within a process chamber and a second gas flow entering second inlet port 108 may be directed to flow across a second portion of the substrate.

Gas delivery system 100 may include a first gas source 110 and a first manifold 160. First manifold 160 may include a first inlet 162, a first outlet 164, and a second outlet 166. First inlet 162 of first manifold 160 may be coupled to first gas source 110. First outlet 164 of first manifold 160 may be coupled to first inlet port 106 of gas interface 105, and second outlet 166 of first manifold 160 may be coupled to second inlet port 108 of gas interface 105.

A flow controller may be structured to gas delivery system 100 to control the flow of gas from gas source 110 through gas delivery system 100. A first flow controller 112 may be positioned inline with first inlet 162 to control the flow rate of gas from first gas source 110 through first manifold 160. In one embodiment, first flow controller 112 may be an automatic flow controller which provides closed loop flow control of gases passing through the automatic flow controller. For example, first flow controller 112 may be a computer controlled mass flow controller (MFC).

An MFC typically comprises an electronic control board, a thermal sensor, and a control valve. During operation, system controller 325 may direct an input signal representing an MFC setpoint to the electronic control board. The input signal received from system controller 325 causes the electronic control board to open the control valve, thereby allowing gas flow through the MFC. A portion of the gas flow through the MFC is directed across the thermal sensor, which generates an output signal proportional to the flow rate of the gas flowing through the MFC. The electronic control board monitors the thermal sensor output signal, compares it to the MFC setpoint, and adjusts the control valve to a setting that provides equalization between the setpoint and the thermal sensor output. Thus, an MFC provides a regulated and highly repeatable flow of gas by means of a closed loop mass flow control system. A wide variety of mass flow controllers are commonly available through manufacturers such as MKS, Horiba, and others to accommodate various fluid properties and fluid flow rates. Mass flow controller 112 is preferably a Series 8100 mass flow controller manufactured by Unit Instruments.

Gas delivery system 100 may also include one or more of isolation valves for controlling the flow of gas through portions of gas delivery system 100. The term “isolation valve” is presently used to describe a valve which may be configured to either an ON or an OFF condition. An isolation valve configured to an ON position allows for the passage of gas through the valve. Conversely, an isolation valve configured to an OFF position prevents the passage of gas through the valve. An isolation valve is typically configured to an ON or OFF condition by means of a pneumatic or electrical input signal received from system controller 325. An isolation valve may be either normally closed or normally open. A normally closed isolation valve is configured to an OFF condition in the absence of an input signal. A normally open isolation valve is configured to an ON condition in the absence of an input signal.

As shown in FIG. 1, isolation valves 113 may be arranged inline with first inlet 162 of first manifold 160 immediately upstream and immediately downstream of flow controller 112. Isolation valves 113 may be selectively configured to control the flow of gas from gas sources 110 into first manifold 160. Isolation valves 113 may include valves manufactured by Veriflo, Fujikin, Nupro, VAN, and Whitey among others.

Gas delivery system 100 may further include a first metering valve 178 positioned inline with first outlet 164 of first manifold 160. First metering valve 178 may be adjusted to apportion the flow of gases passing through first manifold 160 between first outlet 164 and second outlet 166. First metering valve 178 may be a valve containing a variable orifice which is adjusted to control the gas flow capacity of the valve, thereby altering the flow rate of gases passing through the valve body and first outlet 164. In one embodiment, first metering valve 178 may be a needle valve which is manually adjusted to increase or decrease gas flow capacity by the movement of a pointed plug or needle in an orifice or tapered orifice in the valve body. A wide variety of manual needle valves are commercially available to accommodate various fluid properties and fluid flow rates.

In an alternative embodiment, first metering valve 178 may be a computer controlled metering valve which is adjusted by means of an output signal from a computer to control the flow rate of gas passing through first outlet 164. For example, first metering valve 178 may comprise a computer controlled positioning mechanism connected to a variable orifice. The positioning mechanism may be, for example, a rotary stepper motor or a linear actuator which is actuated via an analog or digital voltage control signal to increase or decrease the size of the variable orifice. In one embodiment, system controller 325 may be used to control the operation of first metering valve 178. First metering valve 178 is preferably not a closed loop flow control device, such as a mass flow controller, as first metering valve 178 is intended to apportion the total gas flow passing through flow controller 112 between first outlet 164 and second outlet 166. In a preferred embodiment, first metering valve 178 may be a flowPoint metering valve manufactured by Applied Precision, Incorporated.

In one embodiment, gas delivery system 100 may be structured such that second outlet 166 is more restrictive to gas flow than first outlet 164 when first metering valve 178 is adjusted to a maximum flow capacity, and second outlet 166 is less restrictive to gas flow than first outlet 164 when first metering valve 178 is adjusted to a minimum flow capacity. In this embodiment, first metering valve 178 may be adjusted to increase the gas flow rate through first outlet 164, thereby decreasing the gas flow rate through second outlet 166. Similarly, first metering valve 178 may be adjusted to decrease the gas flow rate through first outlet 164, thereby increasing the gas flow rate through second outlet 166. As a result, first metering valve 178 may be adjusted to apportion the total gas flow entering first inlet 162 between first outlet 164 and second outlet 166.

Various methods may be used to structure gas delivery system 100 such that second outlet 166 is more restrictive to gas flow than first outlet 164 when first metering valve 178 is adjusted to a maximum flow capacity and second outlet 166 is less restrictive to gas flow than first outlet 164 when first metering valve 178 is adjusted to a minimum flow capacity. In one embodiment, a fixed flow restrictor may be placed inline with second outlet 166 to achieve the desired flow restriction. For example, a high purity porous metal flow restrictor manufactured by Mott Corporation may be placed inline with second outlet 166 to “tune” the flow restriction to a desired amount. In an alternative embodiment, a manually adjustable needle valve may be placed inline with second outlet 166 to achieve the desired flow restriction. A wide variety of manual needle valves are commercially available to accommodate various fluid properties and fluid flow rates.

During substrate processing, isolation valves 113 may be configured to an ON condition, thereby allowing gas to flow from first gas source 110 through first flow controller 112. First flow controller 112 may be configured to a first flow setpoint, thereby controlling the flow rate of gases passing through first manifold 160. Gas from first gas source 110 may flow into first outlet 164 and second outlet 166 of first manifold 160, into first inlet port 106 and second inlet port 108, respectively. First metering valve 178 may be adjusted to increase the gas flow rate through first outlet 164, thereby decreasing the gas flow rate through second outlet 166. Alternatively, first metering valve 178 may be adjusted to decrease the gas flow rate through first outlet 164, thereby increasing the gas flow rate through second outlet 166. As a result, the gas flowing through first outlet 164 and second outlet 166 may be apportioned by adjusting first metering valve 178, thereby increasing or decreasing the gas flow across a first and second portion of a substrate contained within a process chamber.

Consequently, gas delivery system 100 may allow for greater control over the flow of gas passing over first and second portions of a substrate positioned in a process chamber, thereby providing enhanced control over the thickness and composition of layers deposited on the substrate. For example, gas delivery system 100 may be integrated with a CVD processing system to apportion the flow of H₂ and TCS; H₂ and DCS; H₂, GeH₄, and SiH₄; or H₂ and SiH₄ across two different portions of a silicon wafer. Alternatively, gas delivery system 100 may be used to apportion the flow of H₂ and TCS; H₂ and DCS; H₂, GeH₄, and SiH₄; or H₂ and SiH₄ in combination with diborane, phosphine, or arsine across two different portion of a silicon wafer.

In the above description, gas delivery system 100 is structured to a gas interface 105 comprising two inlet ports 106 and 108. However, it is to be noted that gas delivery system 100 may be adapted to flow one or more gases to a variety of gas interfaces corresponding to various process chamber configurations.

For example, in one embodiment gas delivery system 100 may be adapted to a gas interface such as gas interface 434 in FIG. 6 by dividing first outlet 164 into two conduits coupled to first outside inlet port 610 and second outside inlet port 615 and coupling second outlet 166 to central inlet port 605. Alternatively second outlet 166 may be divided into two conduits which are coupled to first outside inlet port 610 and second outside inlet port 615 and first outlet 164 may be coupled to central inlet port 605. In either configuration, first metering valve 178 may be used to apportion the gas flow between first outlet 164 and second outlet 166, thereby increasing or decreasing the amount of gas passing across a central portion and first and second outside portions of a substrate.

In another embodiment, gas delivery system 100 may be adapted to a gas interface such as gas interface 434 in FIG. 7 by dividing first outlet 164 into three conduits which are coupled to first outside inlet port 720, second outside inlet port 725, and central inlet port 705; and second outlet 166 may be divided into two conduits which are coupled to first middle inlet port 710 and second middle inlet port 715. Alternatively, second outlet 166 may be divided into three conduits which are coupled to first outside inlet port 720, second outside inlet port 725, and central inlet port 705; and first outlet 164 may be divided into two conduits which are coupled to first middle inlet port 710 and second middle inlet port 715. In either configuration, first metering valve 178 may be used to apportion the gas flow between central, first outside, second outside first middle, and second middle portions of a substrate.

In yet another embodiment, gas delivery system 100 may be adapted to a gas interface such as gas interface 875 in FIG. 8 by dividing first outlet 164 into two conduits coupled to center inlet port 940 and outer inlet port 950 and coupling second outlet 166 to middle inlet port 945. Alternatively second outlet 166 may be divided into two conduits which are coupled to center inlet port 940 and outer inlet port 950 and first outlet 164 may be coupled to middle inlet port 945. In either configuration, first metering valve 178 may be used to apportion the gas flow between first outlet 164 and second outlet 166, thereby increasing or decreasing the amount of gas passing across a central portion and middle and outer annular portions of a substrate.

Gas delivery system 100 may include one or more additional gas sources, flow controllers, and isolation valves connected to first inlet 162 of first manifold 160. Gas delivery system 100 may also include a variety of inline filters, purifiers, pressure transducers, and other such devices as are commonly structured to substrate processing systems. These types of components have been omitted for illustrative purposes so as to not obscure the description of the present invention.

Gas Delivery System 2

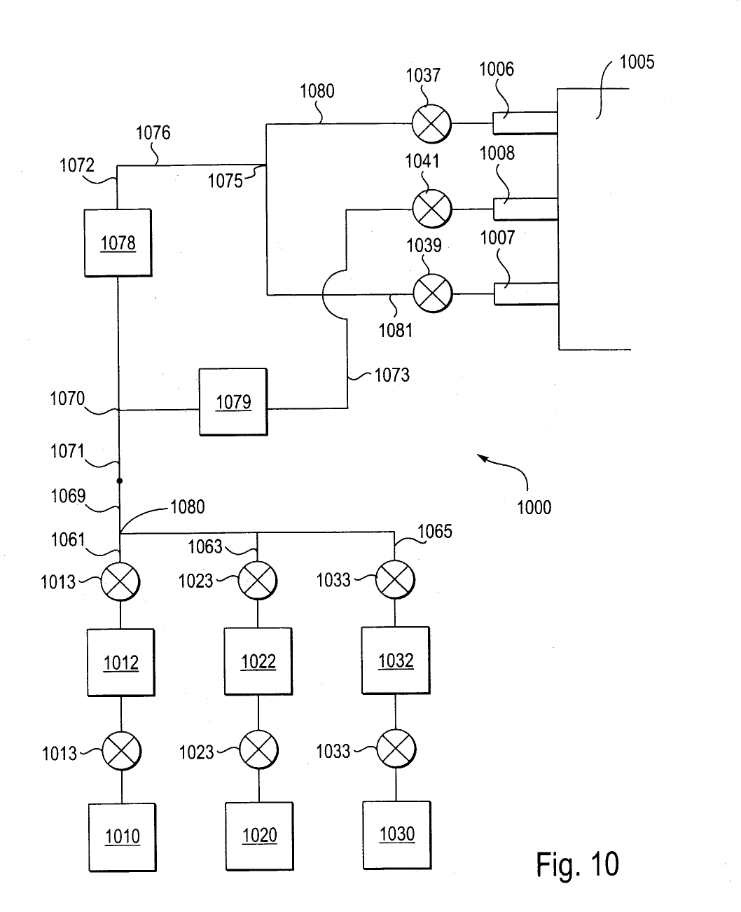

FIG. 10 shows a schematic diagram illustrating another embodiment of a gas delivery system 1000 for controlling the flow of gas to gas interface 1005. Gas interface 1005 may include a first inlet port 1006, a second inlet port 1007, and a third inlet port 1008. In one embodiment, gas interface 1005 may be substantially similar to gas interface 434 in FIG. 6, which is structured to provide three gas flow channels into upper portion 418 of process chamber 400. Consequently, during substrate processing, a first gas flow entering first inlet port 1006 may be directed to flow across a first outside portion of a substrate positioned on susceptor 416; a second gas flow entering second inlet port 1007 may be directed to flow across a second outside portion of the substrate; and a third gas flow entering third inlet port 1008 may be directed to flow across a central portion of the substrate.

Gas delivery system 1000 may further include a first gas source 1010, a second gas source 1020, a third gas source 1030, a first manifold 1060, a second manifold 1070, and a third manifold 1075. First manifold 1060 may include a first inlet 1061, a second inlet 1063, a third inlet 1065, and a first outlet 1069. Second manifold 1070 may include a fifth inlet 1071, a second outlet 1072, and a third outlet 1073. Third manifold 1075 may include a sixth inlet 1076, a fourth outlet 1080, and a fifth outlet 1081.

First inlet 1061, second inlet 1063, and third inlet 1065 of first manifold 1060 may be coupled to first gas source 1010, second gas source 1020, and third gas source 1030, respectively. First outlet 1069 of first manifold 1060 may be coupled to fifth inlet 1071 of second manifold 1070. Second outlet 1072 of second manifold 1070 may be coupled to sixth inlet 1076 of third manifold 1075; third outlet 1073 of second manifold 1070 may be coupled to third inlet port 1008. Fourth outlet 1080 and fifth outlet 1081 of third manifold 1075 may be coupled to first inlet port 1006 and second inlet port 1007, respectively.

Flow controllers may be structured to gas delivery system 1000 to manipulate the flow of gas through gas delivery system 1000. A first flow controller 1012 may be positioned inline with first inlet 1061 to control the flow rate of gas from first gas source 1010 through first manifold 1060. A second flow controller 1022 may be positioned inline with second inlet 1063 to control the flow rate of gas from second gas source 1020 through first manifold 1060. A third flow controller 1032 may be positioned inline with third inlet 1065 to control the flow rate of gas from third gas source 1030 through first manifold 1060. First flow controller 1012, second flow controller 1022 and third flow controller 1032 each may comprise an automatic flow controller, such as a mass flow controller, which provides closed loop gas flow control. First flow controller 1012, second flow controller 1022 and third flow controller 1032 are preferably Series 8100 mass flow controllers manufactured by Unit Instruments.

Gas delivery system 1000 may further include one or more isolation valves for controlling the flow of gas through portions of gas delivery system 1000. As shown in FIG. 10, isolation valves 1013, 1023, and 1033 may be arranged inline with first inlet 1061, second inlet 1063, and third inlet 1065 of first manifold 1060 immediately upstream and immediately downstream of flow controllers 1012, 1022, and 1032 respectively. Isolation valves 1013, 1023, and 1033 may be selectively configured to control the flow of gas from gas sources 1010, 1020, and 1030 into first manifold 1060. Isolation valves 1037 and 1039 may be arranged inline with fourth outlet 1080 and fifth outlet 1081 of third manifold 1075, respectively, and isolation valve 1041 may be arranged inline with third outlet 1073 of second manifold 1070. Isolation valves 1037, 1039, and 1041 may be selectively configured to control the flow of gas from first manifold 1060 to first inlet port 1006, second inlet port 1007, and/or third inlet port 1008, respectively. Isolation valves 1013, 1023, 1033, 1037, 1039, and 1041 may include valves manufactured by Veriflo, Fujikin, Nupro, VAN, and Whitey among others.

Gas delivery system 1000 may further include a first metering valve 1078 and a second metering valve 1079 positioned inline with second outlet 1072 and third outlet 1073 of second manifold 1070. Metering valves 1078 and 1079 may be used to apportion the flow of gases passing through fifth inlet 1071 of second manifold 1070 between second outlet 1072 and third outlet 1073. For example, first metering valve 1078 and second metering valve 1079 may be adjusted so that a greater proportion of gases from fifth inlet 1071 will be diverted into third outlet 1073 than second outlet 1072. Alternatively, first metering valve 1078 and second metering valve 1079 may be adjusted such that a greater proportion of gases from fifth inlet 1071 will be diverted into second outlet 1072 than third outlet 1073.

First metering valve 1078 and second metering valve 1079 each may be a valve containing a variable orifice which is adjusted to control the gas flow capacity of the valve, thereby altering the flow rate of gases passing through the valve body. In one embodiment, first metering valve 1078 and second metering valve 1079 each may be a needle valve which is manually adjusted to increase or decrease gas flow capacity by the movement of a pointed plug or needle in an orifice or tapered orifice in the valve body. A wide variety of manual needle valves are commercially available to accommodate various fluid properties and fluid flow rates.

In an alternative embodiment, first metering valve 1078 and second metering valve 1079 each may be a computer controlled metering valve. For example, first metering valve 1078 and second metering valve 1079 may each comprise a computer controlled positioning mechanism connected to a variable orifice. The positioning mechanism may be, for example, a rotary stepper motor or a linear actuator which is actuated via an analog or digital voltage control signal to increase or decrease the size of the variable orifice. In one embodiment, system controller 325 may be used to control the operation of first metering valve 178. First metering valve 1078 and second metering valve 1079 are preferably not closed loop flow control devices, such as a mass flow controllers, as first metering valve 1078 and second metering valve 1079 are intended to apportion the total gas flow passing through flow controller 112 between first outlet 164 and second outlet 166. In a preferred embodiment, first metering valve 1078 may be a flowPoint metering valve manufactured by Applied Precision, Incorporated.

During substrate processing, isolation valves 1013, 1023, and 1033 may each be configured to an ON condition, thereby allowing gas to flow from first gas source 1010, second gas source 1020, and third gas source 1030 through first flow controller 1012, second flow controller 1022, and third flow controller 1032, respectively. First flow controller 1012 may be configured to a first flow setpoint, second flow controller 1022 may be configured to a second flow setpoint, and third flow controller 1032 may be configured to a third flow setpoint, thereby controlling the flow rate and composition of gases passing through first manifold 1060 and into second manifold 1070. Gases from first gas source 1010, second gas source 1020, and/or third gas source 1030 may mix together within first manifold 1060 and subsequently enter fifth inlet 1071 of second manifold 1070. The gas mixture comprising gas from first gas source 1010, second gas source 1020, and/or third gas source 1030 may then flow into second outlet 1072 and third outlet 1073 of second manifold 1070.

From second outlet 1072 of second manifold 1070, the gas mixture may flow into sixth inlet 1076 of third manifold 1075. From sixth inlet 1076, the gas mixture may flow through fourth outlet 1080 and fifth outlet 1081 of third manifold 1075 into first inlet port 1006 and second inlet port 1007, respectively. From first outlet 1073 of second manifold 1070, the gas mixture may flow into third inlet port 1008.

The composition and flow rate of the gas mixture passing through first inlet port 1006, second inlet port 1007, and third inlet port 1008 may be altered by adjusting the flow setpoint of first flow controller 1012, second flow controller 1022 and/or third flow controller 1032. Additionally, first metering valve 1078 and second metering valve 1079 may be adjusted to apportion the gas flow from fifth inlet 1071 between second outlet 1072 and third outlet 1073. For example, first metering valve 1078 and second metering valve 1079 may be adjusted such that second metering valve 1079 has a higher flow capacity than first metering valve 1078. Consequently, a greater proportion of gases from fifth inlet 1071 will be diverted into third outlet 1073 than second outlet 1072, thereby increasing the gas flow across a central portion of substrate contained within a process chamber and decreasing the gas flow across first and second outside portions of the substrate. Alternatively, first metering valve 1078 and second metering valve 1079 may be adjusted such that second metering valve 1079 has a lower flow capacity than first metering valve 1078, thereby increasing the gas flow across first and second outside portions of a substrate and decreasing the gas flow across a central portion of the substrate.

Consequently, gas delivery system 1000 may allow for greater control over the flow of gas passing over central as well as first and second outside portions of a substrate positioned in a process chamber, thereby providing enhanced control over the thickness and composition of layers deposited on the substrate. For example, in one chemical vapor deposition process embodiment, first gas source 1010 may be H₂, second gas source 1020 may be SiH₄, and third gas source 1030 may be GeH₄. In this embodiment, gas delivery system 1000 may be used to control the composition and flow rate of a mixture of H₂, SiH₄, and GeH₄ across different portions of a silicon wafer. In a second chemical vapor deposition process embodiment, first gas source 1010 may be H₂, second gas source 1020 may be TCS, and third gas source 1030 may be a dopant such as diborane, phosphine, or arsine. In this embodiment, gas delivery system 1000 may be used to control the composition and flow rate of a mixture of H₂, TCS, and a dopant across different portions of a silicon wafer. In a third chemical vapor deposition process embodiment, first gas source 1010 may be H₂, second gas source 1020 may be DCS, and third gas source 1030 may be a dopant such as diborane, phosphine, or arsine. In this embodiment, gas delivery system 1000 may be used to control the composition and flow rate of a mixture of H₂, DCS, and a dopant across different portions of a silicon wafer. In a fourth chemical vapor deposition process embodiment, first gas source 1010 may be H₂, second gas source 1020 may be GeH₄, and third gas source 1030 may be a dopant such as diborane, phosphine, or arsine. In this embodiment, gas delivery system 1000 may be used to control the composition and flow rate of a mixture of H₂, GeH₄, and a dopant across different portions of a silicon wafer. In a fifth chemical vapor deposition process embodiment, first gas source 1010 may be H₂, second gas source 1020 may be SiH₄, and third gas source 1030 may be a dopant such as diborane, phosphine, or arsine. In this embodiment, gas delivery system 1000 may be used to control the composition and flow rate of a mixture of H₂, SiH₄, and a dopant such as diborane, phosphine, or arsine across different portions of a silicon wafer.

In the above description, gas delivery system 1000 is structured to a gas interface 1005 comprising three inlet ports 1006, 1007, and 1008. However, it is to be noted that gas delivery system 1000 may be adapted to flow one or more gases to a variety of gas interfaces corresponding to various process chamber configurations.

For example, in one embodiment gas delivery system 1000 may be adapted to a gas interface such as gas interface 434 in FIG. 7 by dividing third outlet 1073 into three conduits which may be coupled to first outside inlet port 720, second outside inlet port 725, and central inlet port 705; fourth outlet 1080 and fifth outlet 1081 may be coupled to first middle inlet port 710 and second middle inlet port 715. In this configuration, first metering valve 1078 and second metering valve 1079 may be adjusted to apportion the gas flow from fifth inlet 1071 between central inlet port 705, first outside inlet port 720, and second outside inlet port 725; and between first middle inlet port 710 and second middle inlet port 715. Consequently, gas delivery system 1000 may be used to control the composition and gas flow rate across central, first outside, second outside, first middle, and second middle portions of a substrate, thereby providing enhanced control over the thickness and composition of layers deposited on the substrate.

In another embodiment, gas delivery system 1000 may be adapted to a gas interface such as gas interface 875 in FIG. 8, which is structured to provide three gas flow channels into an interior portion of process chamber 800 through showerhead 815. For example, third outlet 1073 may be coupled to middle inlet port 945. Similarly, fourth outlet 1080 and fifth outlet 1081 may be coupled to center inlet port 940 and outer inlet port 950, respectively. In this configuration, first metering valve 1078 and second metering valve 1079 may be adjusted to apportion the gas flow from fifth inlet 1071 between center inlet port 940 and outer inlet port 950; and between middle inlet port 945. Consequently, gas delivery system 1000 may be used to control the composition and gas flow rate across a central portion and middle and outer annular portions of a substrate, thereby providing enhanced control over the thickness and composition of layers deposited on the substrate.

Gas delivery system 1000 may also include a variety of inline filters, purifiers, pressure transducers, and other such devices as are commonly structured to substrate processing systems. These types of components have been omitted for illustrative purposes so as to not obscure the description of the present invention.

Processing Operation

As previously discussed in reference to FIG. 3, system controller 325 may control the operation of processing system 300 according to an instruction set defined by system control software. For example, system controller 325 may control all of the activities of processing chambers 306, 308, and 310 by means of a chamber manager subroutine within the system control software.

System controller 325 may also control the distribution of gases to process chambers 306, 308, and 310 by means of a gas distribution subroutine within the system control software. During processing, the gas distribution subroutine may instruct the system controller to monitor the isolation valves, flow controllers, computer controlled metering valves, and other such components which comprise the gas delivery system in order to determine which components need to be operated based upon the process parameters contained within a particular process recipe. The system controller may then direct the control of those components responsive to process recipe requirements.

During operation, a system operator may create a process recipe which contains all process parameters necessary to carry out a particular sequence of process steps within a process chamber. A process recipe is typically comprised of one or more process steps. Each process recipe step may contain a set of variables that define various process parameters for that recipe step, such as isolation valve, flow controller, and computer controlled metering valve setpoints. The process recipe variables may be stored in a table of instructions on a computer readable medium connected to system controller 325. For example, computer controlled metering valve setpoints may be stored in a text table of valve setpoint instructions on a hard drive connected to system controller 325. Alternatively, the table of instructions may contain an algorithm for determining computer controlled metering valve setpoints based upon other process parameter settings or data inputs.

The computer controlled gas delivery system of the present invention may be used to automatically adjust metering valve, flow controller and isolation valve settings between process recipes. For example, a first wafer may be processed using a first group of computer controlled metering valve and flow controller settings corresponding to a first process recipe. After the first wafer is removed from the process chamber, a second wafer may be processed using a second group of computer controlled metering valve and flow controller settings corresponding to a second process recipe.

Typically, metering valve setpoints which produce optimal uniformity for a first group of flow controller settings may produce less than optimal uniformity when used in conjunction with a second group of flow controller settings. However, the gas distribution system of the present invention may be used to automatically adjust computer controlled metering valve setpoints between process recipes, thereby allowing for optimal process uniformity while depositing layers with varying composition and/or thickness on different substrates using different process recipes. For example, a first process recipe may include a first group of metering valve settings which provides optimal uniformity across a first layer deposited using a first group of flow controller and isolation valve settings. A second process recipe may include a second group of metering valve settings which provides optimal uniformity across a second layer deposited using a second group of flow controller and isolation valve settings.

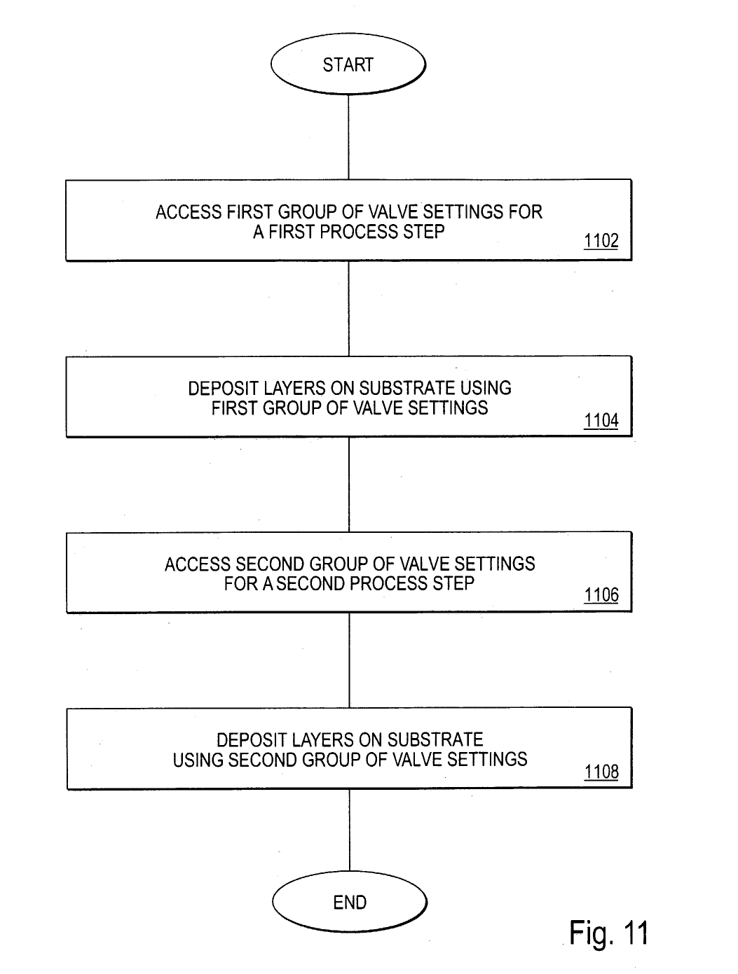

Additionally, the computer controlled gas delivery system of the present invention may be used to change process parameters between recipe steps in a single process recipe. As a result, the gas distribution subroutine may instruct the system controller to alter computer controlled metering valve, flow controller, and isolation valve settings responsive to process parameter changes between process recipe steps. FIG. 11 shows a flow diagram illustrating one embodiment of performing a first process step and a second process step on a substrate using the gas distribution system of the present invention. At step 1102, the processing system may access a first group of valve settings for a first process step to be performed on the substrate. The first group of valve settings may include computer controlled metering valve, flow controller, and isolation valve setpoints corresponding to a first process step within a first process recipe. At step 1104, the processing system may perform the first process step on the substrate using the first group of valve settings. At step 1106, the processing system may access a second group of valve settings for a second process step to be performed on the substrate. The second group of valve settings may include computer controlled metering valve, flow controller, and isolation valve setpoints corresponding to a second process step within the first process recipe. At step 1108, the processing system may perform the second process step on the substrate using the second group of valve settings. After the second process step is complete, the substrate may be removed from the process chamber and another substrate may be processed. In alternative embodiments, additional process steps may be performed on a substrate using additional process steps and valve settings within the first process recipe.

Typically, metering valve setpoints which produce optimal uniformity for a first group of flow controller settings may produce less than optimal uniformity when used in conjunction with a second group of flow controller settings. However, the gas distribution system of the present invention may be used to automatically adjust computer controlled metering valve setpoints between recipe steps in a single process recipe, thereby allowing for optimal process uniformity while depositing layers with varying composition and/or thickness over a substrate during a single process recipe. For example, a first recipe step may include a first group of metering valve settings which provides optimal uniformity across a first layer deposited using a first group of flow controller and isolation valve settings. A second recipe step may include a second group of metering valve settings which provides optimal uniformity across a second layer deposited using a second group of flow controller and isolation valve settings.

As previously discussed, an example process recipe 1405 is depicted graphically in FIG. 14A. Similarly, FIG. 14B graphically depicts inner metering valve setpoint 1425 and outer metering valve setpoint 1430 for purge process step 1410. Hence, prior to performing process recipe 1405, the processing system may access inner metering valve setpoints 1425 and outer metering valve setpoints 1430 and adjust corresponding computer controlled metering valves according to the voltage values contained within purge process step 1410.

During operation, the gas distribution subroutine may direct system controller 325 to actuate one or more computer controlled metering valves by means of an output control signal. FlowPoint computer controlled metering valves manufactured by Applied Precision, Inc. provide for 256 discrete setpoints between 5% and 100% flow for a 0-10 Volt analog input signal. Hence, a system controller adapted to control one or more flowPoint computer controlled metering valves may generate a 0-10 Volt control signal for each flowPoint computer controlled metering valve structured to the gas distribution system. Other types of computer controlled metering valves may require alternative output signals, such as pneumatic, digital, or optical output signals.

In-Line Metrology

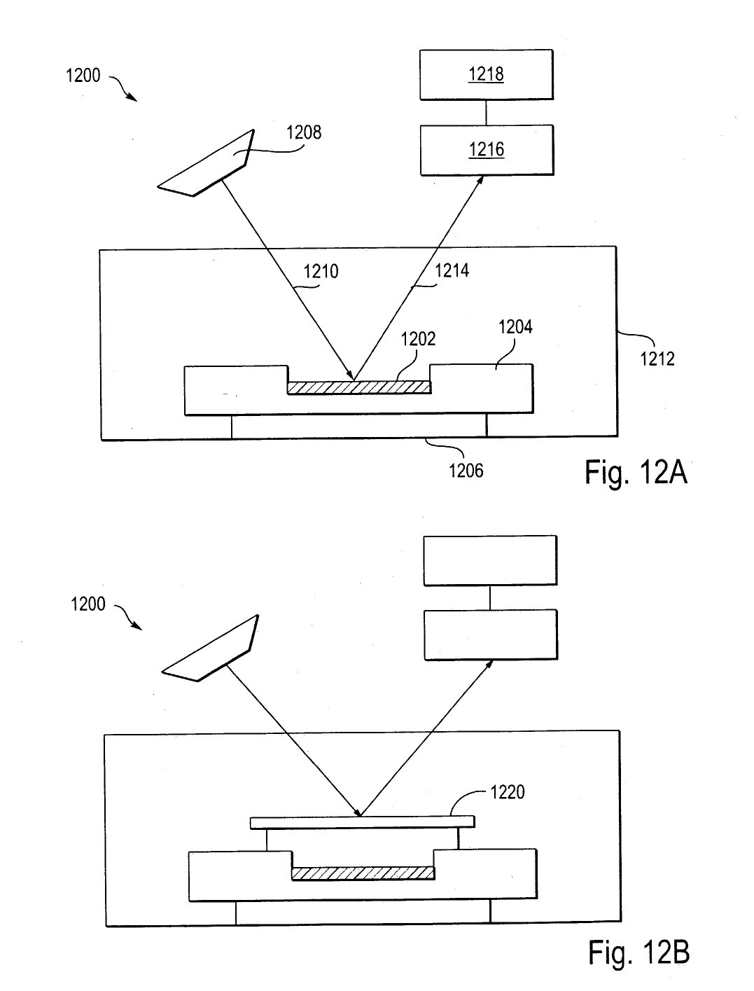

Referencing FIG. 3, processing system 300 may incorporate a metrology chamber 312 to measure film thickness uniformity of a wafer processed by process chambers 306, 308, and 310. FIGS. 12A and 12B are schematic diagrams illustrating one embodiment of a metrology chamber 1200 for use with processing system 300. Metrology chamber 1200 may be substantially similar to metrology chamber 312 described above with reference to FIG. 3. Alternatively, metrology chamber 700 may be incorporated into cool-down chamber 314 attached to processing system 300.

Referencing FIG. 12A, a reference sample 1202 may rest in a recess of a chuck 1204 that is part of a stage 1206 disposed within metrology chamber 1200. A light source 1208 may provide a light signal 1210, such as infrared radiation, that passes through a portion of chamber body 1212 to reference sample 1202. After light signal 1210 reaches reference sample 1202, a reflected light signal 1214 may be reflected towards a detector 1216. Detector 1216 may be coupled to a computer system 1218, which records the spectrum of the reference sample. Reference sample 1202 should not be set too deep in stage 1206 because the distance between light source 1208 and reference sample 1202 should be close to the distance between light source 1208 and a wafer 1220 placed within chamber body 1212 to ensure an accurate measurement. Computer system 1218 may be provided with a storage device, such as a hard drive, to store both a reference spectrum and a spectrum from each wafer 1220 that is measured. In addition, computer system 1218 may include a processor that executes an algorithm for comparing the reference sample spectrum with the spectrum from each wafer 1220 that is measured.

Although light source 1208 and detector 1216 are shown outside chamber body 1212, it is to be appreciated that light source 1208 and detector 1216 can also be located within chamber body 1212. Additionally, computer system 1218 may be integrated with metrology chamber 1200, or it can be integrated within processing system 300. For example, computer system 1218 may be integrated within system controller 325.

During operation, a substrate which has been processed in at least one of process chambers 306, 308, and 310 may be transferred to metrology chamber 312 by a substrate transfer robot. Metrology chamber 312 may measure one or more attributes of a layer deposited on the wafer, such as thickness uniformity, dopant incorporation, resistivity, and/or surface roughness. The substrate transfer robot may subsequently transfer the substrate to load-lock chamber 304 for removal from processing system 300.

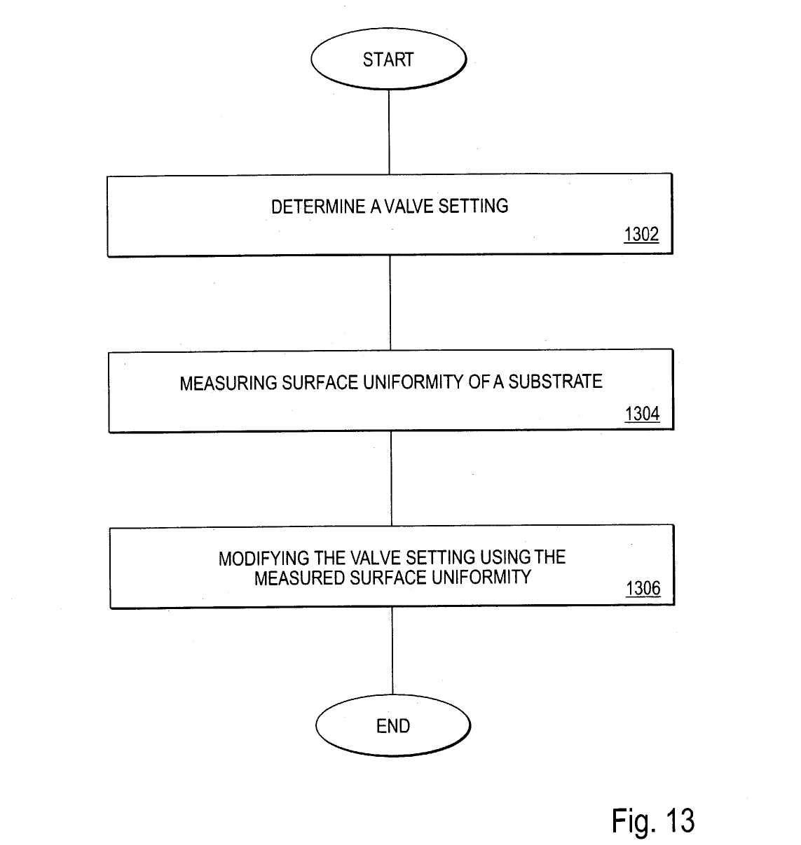

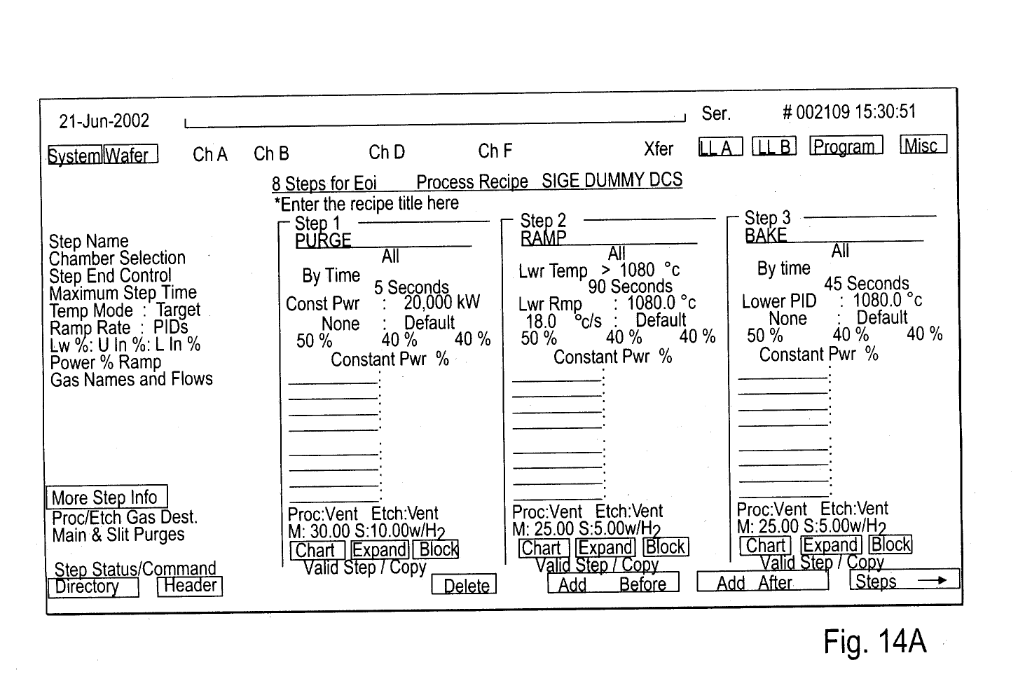

Computer controlled metering valve variables contained within a process recipe may be modified based upon measurements provided by metrology chamber 312. FIG. 13 represents a flow diagram illustrating one possible method of modifying computer controlled metering valve variables using measurements from metrology chamber 312. At step 1302, processing system 300 determines the value of a computer controlled metering valve variable contained within a particular process recipe. At step 1304, metrology chamber 312 measures the film thickness uniformity of a substrate processed by the process recipe. At step 1306, the metrology chamber provides the measurements to the system controller, and system controller 325 modifies the computer controlled metering valve variable within the process recipe in order to optimize film thickness uniformity on subsequently processed substrates. System controller 325 may utilize various software programs and/or algorithms to modify computer controlled metering valve variables within process recipes.

Modifying computer controlled metering valve variables using measurements taken by in-line metrology chamber 312 may greatly enhance process uniformity on subsequently processed substrates, thereby automatically improving the process performance of processing system 300. As processes are performed on successive substrates, computer controlled metering valve variables may be further modified to optimize process uniformity.

In the foregoing specification, the invention has been described with reference to specific exemplary embodiments thereof. However, it should be evident to one skilled in the art that various modifications and changes may be made without departing from the broader spirit and scope of the invention as set forth in the appended claims. Accordingly, the specification and drawings are to be regarded in an illustrative rather than a restrictive sense.

We claim:

1. A fluid delivery system for providing fluids to a substrate processing system, the fluid delivery system comprising:
a manifold having a first inlet, a first outlet, and a second outlet, wherein the first outlet and the second outlet are coupled to the substrate processing system;
a conduit for coupling a fluid to the first inlet;
a computer controlled flow controller for controlling the flow of the fluid through the conduit;
a computer controlled metering valve coupled to the first outlet; and
a computer for controlling the computer controlled flow controller and the computer controlled metering valve.

2. The fluid delivery system of claim 1, wherein the computer controlled metering valve may be adjusted to apportion the flow of the fluid entering the first inlet between the first outlet and the second outlet.

3. The fluid delivery system of claim 1, wherein the computer controlled metering valve comprises a positioning mechanism coupled to a variable orifice valve assembly, and the positioning mechanism is controlled by input signals received from the computer.

4. The fluid delivery system of claim 1, wherein the computer controlled flow controller is a mass flow controller.

5. The fluid delivery system of claim 1, further comprising a first isolation valve coupled to the conduit upstream of the computer controlled flow controller and a second isolation valve coupled to the conduit downstream of the computer controlled flow controller.

6. The fluid delivery system of claim 1, wherein the computer controlled metering valve includes a variable orifice which may be adjusted to provide a minimum fluid flow rate and a maximum fluid flow rate.

7. The fluid delivery system of claim 6, wherein the second outlet is more restrictive to fluid flow than the first outlet when the computer controlled metering valve is adjusted to a maximum fluid flow rate, and the second outlet is less restrictive to fluid flow than the first outlet when the computer controlled metering valve is adjusted to a minimum fluid flow rate.

8. The fluid delivery system of claim 6, wherein adjusting the computer controlled metering valve to increase the fluid flow rate through the first outlet decreases the fluid flow rate through the second outlet.

9. The fluid delivery system of claim 6, wherein adjusting the computer controlled metering valve to decrease the fluid flow rate through the first outlet increases the fluid flow rate through the second outlet.

10. The fluid delivery system of claim 1, wherein the computer comprises a system controller and system control software for controlling the operation of the computer controlled metering valve and the computer controlled flow controller.

11. The fluid delivery system of claim 10, wherein a process recipe comprising one or more process recipe steps may be defined such that the system controller automatically adjusts the computer controlled flow controller and the computer controlled metering valve between process steps.

12. A fluid delivery system for providing fluids to a substrate processing system, the fluid delivery system comprising:
a first manifold having a first inlet, a first outlet, and a second outlet, wherein the first outlet and the second outlet are coupled to the substrate processing system;
a first conduit for coupling a first fluid to the first inlet;
a first flow controller for controlling the flow of the first fluid through the first conduit;
a first metering valve coupled to the first outlet; and
a second metering valve coupled to the second outlet.

13. The fluid delivery system of claim 12, further comprising:
a second conduit for coupling a second fluid to the first inlet;
a second flow controller for controlling the flow of the second fluid through the second conduit;
a third conduit for coupling a third fluid to the first inlet; and
a third flow controller for controlling the flow of the third fluid through the third conduit.

14. The fluid delivery system of claim 13, wherein the first fluid comprises H₂, the second fluid comprises SiH₄, and the third fluid comprises GeH₄.

15. The fluid delivery system of claim 13, wherein the first fluid comprises H₂, the second fluid comprises TCS, and the third fluid is a dopant.

16. The fluid delivery system of claim 15, wherein the dopant is one of diborane, phosphine, or arsine.

17. The fluid delivery system of claim 13, wherein the first fluid comprises H₂, the second fluid comprises DCS, and the third fluid is a dopant.

18. The fluid delivery system of claim 17, wherein the dopant is one of diborane, phosphine, or arsine.

19. The fluid delivery system of claim 13, wherein the first fluid comprises H₂, the second fluid comprises GeH₄, and the third fluid is a dopant.

20. The fluid delivery system of claim 19, wherein the dopant is one of diborane, phosphine, or arsine.

21. The fluid delivery system of claim 13, wherein the first fluid comprises H₂, the second fluid comprises SiH₄, and the third fluid is a dopant.

22. The fluid delivery system of claim 21, wherein the dopant is one of diborane, phosphine, or arsine.

23. The fluid delivery system of claim 12, wherein the first metering valve and the second metering valve may be adjusted to apportion the flow of the first fluid entering the first inlet between the first outlet and the second outlet.

24. The fluid delivery system of claim 12, wherein the first metering valve and the second metering valve each comprise a computer controlled metering valve having a positioning mechanism coupled to a variable orifice valve assembly.

25. The fluid delivery system of claim 12, wherein the first flow controller is a computer controlled mass flow controller.

26. The fluid delivery system of claim 12, further comprising a system controller and system control software for operating the system controller, wherein:
the first metering valve and the second metering valve each comprise a computer controlled metering valve having a positioning mechanism coupled to a variable orifice valve assembly;
the first flow controller is a mass flow controller; and
the system controller controls the operation of the first metering valve, the second metering valve, and the first flow controller.

27. The fluid delivery system of claim 12, wherein a process recipe comprising one or more process recipe steps may be defined such that the system controller automatically adjusts the first flow controller, the first metering valve, and the second metering valve between process steps.

28. The fluid delivery system of claim 27 wherein the system controller comprises:
a processor;
an input/output device;
a memory; and
a system control program stored in the memory that, when executed by the processor, causes the system controller to control the first metering valve and the second metering valve.

29. The fluid delivery system of claim 28 wherein the system control program comprises a gas distribution program code.

30. The fluid delivery system of claim 29 wherein the gas distribution program code comprises a metering valve setting instruction set.

31. The fluid delivery system of claim 30 wherein the metering valve setting instruction set comprises a table of valve settings.

32. The fluid delivery system of claim 31 wherein the metering valve setting instruction set further comprises an algorithm to modify the table of valve settings.

33. The fluid delivery system of claim 32 further comprising a metrology chamber to determine surface uniformity measurements for a substrate.

34. The fluid delivery system of claim 33 wherein the metrology chamber provides surface uniformity measurements to the system controller.

35. The fluid delivery system of claim 34 wherein the algorithm uses the surface uniformity measurements to modify the table of valve settings.

36. A method of delivering fluids to a substrate processing system, the method comprising:
providing a first manifold having a first inlet, a first outlet, and a second outlet, wherein the first outlet and the second outlet are coupled to the substrate processing system;
providing a conduit for coupling a fluid to the first inlet;
providing a computer controlled flow controller for controlling the flow of the fluid through the conduit;
providing a computer controlled metering valve coupled to the first outlet for apportioning the flow of the fluid through the conduit between the first outlet and the second outlet;
controlling the flow of the fluid through the conduit; and
apportioning the flow of the fluid between the first outlet and the second outlet.

37. A method of delivering fluids to a substrate processing system, the method comprising:
providing a first manifold having a first inlet, a first outlet, and a second outlet, wherein the first outlet and the second outlet are coupled to the substrate processing system;
providing a first conduit for coupling a first fluid to the first inlet;
providing a first flow controller for controlling the flow of the first fluid through the first conduit;
providing a first metering valve coupled to the first outlet and a second metering valve coupled to the second outlet for apportioning the flow of the first fluid through the first conduit between the first outlet and the second outlet;
controlling the flow of the first fluid through the first conduit; and
apportioning the flow of the first fluid between the first outlet and the second outlet.

38. A method of delivering fluids to a substrate processing system, the method comprising:
accessing a first group of valve settings for a first process;
depositing layers on a first substrate using the first group of valve settings;
accessing a second group of valve settings for a second process; and
depositing layers on a second substrate using the second group of valve settings.

39. The method of claim 38, wherein the first group of valve settings is used to create a first gas distribution of H₂, SiH₄, and GeH₄ across the surface of the first substrate and the second group of valve settings is used to create a second gas distribution of H₂, SiH₄, and GeH₄ across the surface of the second substrate.

40. The method of claim 38 further comprising placing the first substrate in a process chamber.

41. The method of claim 40 further comprising removing the first substrate from the process chamber after depositing one or more layers on the first substrate using the first group of valve settings.

42. The method of claim 41 further comprising placing the second substrate in the process chamber after removing the first substrate from the process chamber.

43. A method of delivering fluids to a substrate processing system, the method comprising:
determining a valve setting;
depositing a layer on a substrate using the valve setting;
measuring a surface uniformity of the deposited layer, thereby generating a surface uniformity measurement; and
modifying the valve setting using the surface uniformity measurement.

44. The method of claim 43 wherein determining the valve setting comprises receiving the valve setting from an input/output device.

45. The method of claim 43 wherein measuring the surface uniformity of the deposited layer comprises:
measuring the thickness of the deposited layer at a first location;
measuring the thickness of the deposited layer at a second location; and
comparing the thickness of the deposited layer at the first location with the thickness of the deposited layer at the second location.

46. The method of claim 43 wherein modifying the valve setting comprises applying an algorithm using the surface uniformity measurement.

47. The method of claim 43 wherein the deposited layer is SiGe.

48. A method of delivering fluids to a substrate processing system, the method comprising:
accessing a first valve setting;
depositing a first layer on a substrate;
accessing a second valve setting; and
depositing a second layer on the substrate.

49. The method of claim 48 further comprising placing the substrate in a process chamber before depositing the first layer.

50. The method of claim 49 further comprising removing the substrate from the process chamber after depositing the second layer.

51. The method of claim 48, wherein the first valve setting is used to create a first gas distribution of H₂, SiH₄, and GeH₄ across a surface of the substrate and the second valve setting is used to create a second gas distribution of H₂, SiH₄, and GeH₄ across the surface of the substrate.

52. A process recipe for directing a substrate processing system to deliver processing fluids to a substrate processing chamber, the process recipe comprising:
instructions for controlling a computer controlled flow controller which controls the flow of a fluid through an inlet of a manifold, the manifold having a first outlet and a second outlet coupled to the substrate processing chamber; and
instructions for controlling a computer controlled metering valve which apportions the flow of the fluid between the first outlet and the second outlet.

53. A process recipe for directing a substrate processing system to deliver processing fluids to a substrate processing chamber, the process recipe comprising:
instructions for controlling a computer controlled flow controller which controls the flow of a fluid through an inlet of a first manifold, the manifold having a first outlet coupled to an inlet of a second manifold;
instructions for controlling a first computer controlled metering valve which apportions the flow of the fluid between a first outlet and a second outlet of the second manifold, wherein the first outlet and the second outlet of the second manifold are coupled to the substrate processing chamber; and
instructions for controlling a second computer controlled metering valve which apportions the flow of the fluid between the first outlet and the second outlet of the second manifold.

54. A process recipe for directing a substrate processing system to deliver processing fluids to a substrate processing chamber, the process recipe comprising:
a first recipe step having a first instruction for controlling a computer controlled metering valve; and
a second recipe step having a second instruction for controlling the computer controlled metering valve.
